(19) United States
(12) Patent Application Publication
(10) Pub. No.: US 2009/0144595 A1
(43) Pub. Date: Jun. 4, 2009

(54) BUILT-IN SELF-TESTING (BIST) OF FIELD PROGRAMMABLE OBJECT ARRAYS

(75) Inventors: Richard D. Reohr, JR., Hillsboro, OR (US); Matthew F. Barr, Allen, TX (US); Richard David Wiita, East Bethel, MN (US)

Correspondence Address: STOEL RIVES LLP - PDX, 900 SW FIFTH AVENUE, SUITE 2600, PORTLAND, OR, 97204-1268, US

(73) Assignee: MathStar, Inc., Hillsboro, OR (US)

(21) Appl. No.: 12/023,825

(22) Filed: Jan. 31, 2008

Related U.S. Application Data
(60) Provisional application No. 60/991,695, filed on Nov. 30, 2007.

(51) Int. Cl. G01R 31/3187; G06F 11/26; G06F 11/27

(52) U.S. Cl. 714/732; 714/733; 714/724; 714/E11.169; 714/E11.159

(57) ABSTRACT

A field programmable object array integrated circuit has built-in self-testing capability. The integrated circuit comprises an array of programmable objects, a plurality of interfaces, and a controller. The array of objects is designed to operate at an operational clock speed during non-testing operation, wherein the design of the objects is not constrained to require within an object extra circuitry not essential to non-testing operation to facilitate built-in self-testing. The interfaces are connected to the objects to enable communication with the objects and to thereby facilitate built-in self-testing of the objects. The controller causes a selected subset of the objects to be activated and configured for testing, to stimulate the selected subset for some time with an input test pattern delivered via the interfaces while the selected subset of objects operates at the operational clock speed, and to observe a response of the selected subset of objects.

### RELATED APPLICATIONS

This application claims the benefit under 35 U.S.C. § 119(e) of U.S. Provisional Application No. 60/991,695, filed Nov. 30, 2007, which is hereby incorporated by reference in its entirety.

### TECHNICAL FIELD

The field of the present disclosure relates to systems, methods and apparatus for testing integrated circuits.

### BACKGROUND INFORMATION

Even the best integrated circuit designs are subject to flaws, such as physical flaws or timing flaws. The flaws may arise during manufacturing or at anytime over the life of the chip. Thus, integrated circuits are typically tested before and/or after packaging.

Testing integrated circuits may be costly in terms of test-cycle duration and engineering time devoted to designing tests and examining test results. Further, integrated circuits may have a plethora of inputs and outputs that are not accessible via external pads or pins. As a result, internal defects may not be readily discernable by simply using externally accessible inputs and outputs. Accordingly, many integrated circuits are designed for test, i.e., having testability capability. One such technique is known as built-in self-testing (BIST). According to this technique, an integrated circuit is designed to include BIST circuitry, which enables application of a test pattern to the integrated circuit's functional circuitry (which is modified to be BIST-operable) and observation of a response of the functional circuitry to the test pattern. If the observed response matches an expected value, the functional circuitry can be considered to be operating properly.

Field-programmable object arrays (FPOAS) have been developed to fill a gap between field-programmable gate arrays (EPGAs) and application-specific integrated circuits (ASICs). While FPGAs are programmable at the gate level, they may not be able to keep up with some demanding applications, such as machine-vision, video application, medical imaging, and radar processing, for example. While ASICs can be designed to have the processing power to meet those demands and others, the time and cost required to develop an ASIC may be too great in certain situations. FPOAs can sometimes be suitable for demanding applications, such as those and others, while the programmable nature of an FPOA (like an FPGA) can considerably alleviate development time and costs, as compared to an ASIC.

A typical FPOA comprises a number of programmable objects along with a programmable high-speed interconnection network. The objects in an FPOA, as compared to the relatively simple gates of an FPGA, can be considerably more complex, while the number of objects in a typical FPOA is usually much less than the number of gates in an FPGA. Examples of object types include arithmetic logic units (ALUs), multiply/accumulate units (MACs), and memory banks such as register files (RFs). An FPOA's objects, which are typically designed in advance to have timing closure at high clock speeds, can be combined in intuitive ways to provide powerful processing capability, which is especially well suited for byte-width, word-width, or other multi-bit data.

### SUMMARY

The unique architecture and features of FPOAs present challenges and opportunities for built-in self-testing of FPOAs.

According to one embodiment, an integrated circuit with built-in self-testing capability comprises an array of programmable objects, a plurality of interfaces, and a controller. The array of programmable objects may be designed to operate at an operational clock speed during non-testing operation, wherein the design of the objects is not constrained to require within an object extra circuitry not essential to non-testing operation to facilitate built-in self-testing. The plurality of interfaces may be connected to the objects to enable communication with the objects and to thereby facilitate built-in self-testing of the objects. The controller may be operably connected to the objects and to the interfaces and configured to cause a selected subset of the objects to be activated and configured for testing, to stimulate the selected subset of objects for a given time with an input test pattern delivered via one or more of the plurality of interfaces while the selected subset of objects operates at the operational clock speed, and to observe a response of the selected subset of objects for testing purposes.

According to another embodiment, a method tests an integrated circuit comprising in substantial part an array of objects in a central region of the integrated circuit and further comprising registers outside of the central region. The test method may comprise (a) establishing a subset of the objects as a set of objects-under-test, (b) configuring the array of objects so that the set of objects-under-test and a set of the registers communicate via a set of intermediate objects in the array, (c) testing the set of objects-under-test, (d) establishing a new set of objects-under-test as a different subset of the objects, and (e) repeating steps (b), (c), and (d) until every object in the array has been included in at least one set of objects-under-test. Step (c) may include setting the set of objects-under-test into a configuration, stimulating the set of objects-under-test with a test pattern via the set of intermediate objects while the set of object-under-test operates, and receiving an output pattern from the set of objects-under-test in response to the test pattern, the output pattern received at the set of registers via the set of intermediate objects.

According to still another embodiment, a method tests an integrated circuit comprising an array of objects. The method may comprise fully powering up a set of objects to be tested, partially powering up another set of objects to allow unidirectional segmented buses included therein to transfer data to and from the fully-powered-up set of objects, fully powering down any remaining objects of the array, thereby limiting the array's power consumption, and transmitting a test pattern to the fully powered-up set of objects and an output pattern from the fully powered-up set of objects via the partially powered-up set of objects, the output pattern generated by the fully powered-up set of objects in response to the test pattern.

As one skilled in the art will appreciate in view of the teachings herein, certain embodiments may be capable of achieving certain advantages, including by way of example and not limitation one or more of the following: (1) the ability to reduce power consumption and heat generation during testing, (2) the ability to perform testing at full clock speed for object's core functionality; (3) little or no imposition of dedicated testing circuitry in objects, thereby allowing smaller footprint that provides greater core operational speeds and/or usable functionality; (4) flexibility to adjust the complexity of testing by controlling the size, shape, and/or location of selected portions of the chip tested together, thereby enabling a trade-off among thoroughness of testing, observability, and other factors such as, for example, speed and power consumption; (5) the ability to test objects to a statistically significant degree of thoroughness by pseudo-randomly setting input stimulus as well as the configurations or set-up of objects-under-test; (6) the ability to test operation of an array or other core to a statistically significant degree using communication circuitry on the periphery of the array or other core and therefore not impacting the design of the array or other core; (7) the ability to test long delay paths; (8) enabling the use of simpler board and power supply designs; (9) reduced current surges and associated voltage dips during testing; and (10) the ability to perform testing on a variety of unique objects without altering the test method (i.e., the testing technique is invariant to the object's design). These and other advantages of various embodiments will be apparent upon reading the following.

### BRIEF DESCRIPTION OF THE DRAWINGS

FIG. 1 is an simplified block diagram of one example of an FPOA.

FIG. 2 is a diagram illustrating one example of an interconnect framework that objects may use to communicate with each other in the example FPOA of FIG. 1.

FIG. 3 is a block diagram illustrating examples of communication channels for an object in an FPOA.

FIG. 4 is a high-level logic diagram illustrating registers and multiplexers used to facilitate party line communication, according to one example of an FPOA object.

FIG. 5 is a diagram of one example of an FPOA object.

FIG. 6 is a state transition diagram illustrating one example of a startup process for an FPOA.

FIG. 7 is a block diagram illustrating one example of scan chains used to program a objects in an FPOA.

FIG. 8 is a block diagram illustrating BIST testing of an FPOA utilizing a rectangle under test, according to one embodiment.

FIG. 9A is a flowchart illustrating a method of testing an FPOA, according to one embodiment.

FIG. 9B is a flowchart illustrating a method of configuring and testing a subset of objects, according to one embodiment.

FIG. 10A is a flowchart illustrating a method of configuring and testing a subset of objects, according to another embodiment.

FIG. 10B is a flowchart illustrating a method of testing an FPOA, according to another embodiment.

FIG. 11 is a block diagram illustrating various components used to test an FPOA, according to one embodiment.

FIG. 12 is a block diagram of a BIST controller according to one embodiment.

FIG. 13 is a block diagram illustrating party line retiming according to one embodiment.

FIG. 14 is a block diagram illustrating coordinates for a rectangle under test, according to one embodiment.

FIG. 15 is a block diagram illustrating a BIST Signal Block according to one embodiment.

FIG. 16 is a block diagram illustrating a silicon object interface (SOI) according to one embodiment.

### DETAILED DESCRIPTION

With reference to the above-listed drawings, this section describes particular embodiments and their detailed construction and operation. The embodiments described herein are set forth by way of illustration only. In light of the teachings herein, those skilled in the art will recognize that there may be equivalents to what is expressly or inherently taught herein. For example, variations can be made to the embodiments described herein and other embodiments are possible. It is not always practical to exhaustively catalog all possible embodiments and all possible variations of the described embodiments.

For the sake of clarity and conciseness, certain aspects of components or steps of certain embodiments are presented without undue detail where such detail would be apparent to those skilled in the art in light of the teachings herein and/or where such detail would obfuscate an understanding of more pertinent aspects of the embodiments.

### Architectural Overview

Before describing detailed examples of BIST for FPOAs, the FPOA architecture and associated concepts are first described in this and the subsequent three subsections.

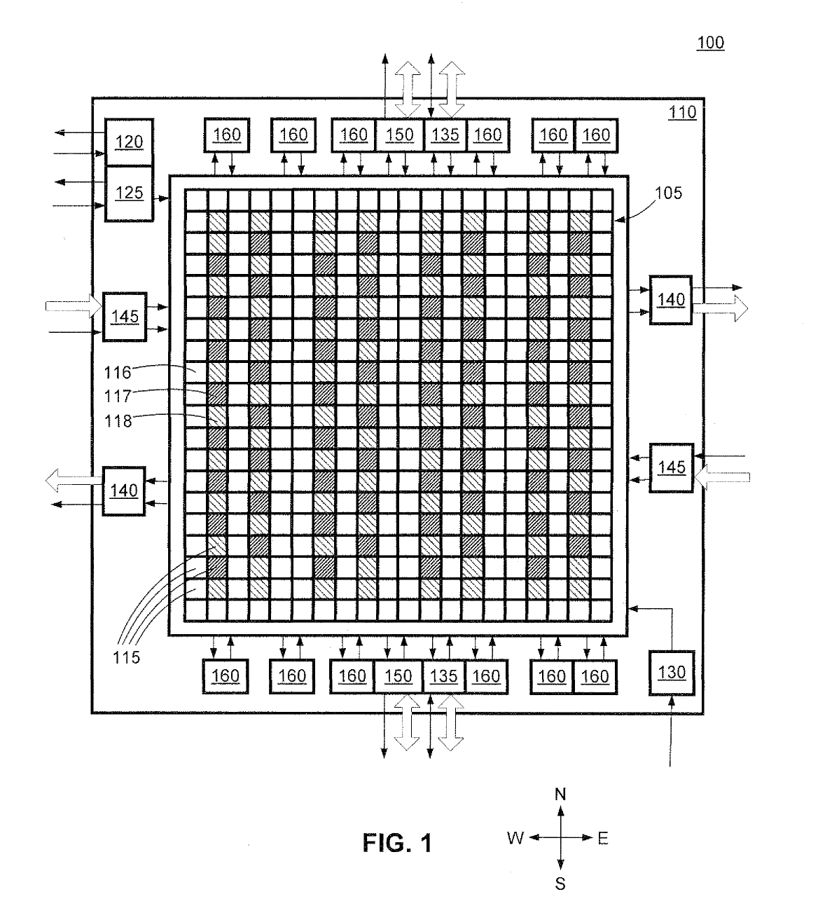

FIG. 1 illustrates one example FPOA 100, which includes a plurality of objects 115 divided between two regions: a core region 105 and a non-core or periphery region 110. The core region 105 includes a plurality of distinct programmable objects 115 that perform most of the computations or other operational functionality within the FPOA 100. The core region 105 may be a substantial part of the FPOA 100 in terms of area and functionality, as compared to the periphery region 110. The core region 105 may be centrally located within the periphery region 110, as illustrated in FIG. 1, or located elsewhere according to any other feasible physical layout. The periphery region 110 can comprise I/O (input/output) interfaces, control and/or set-up circuitry, and/or other support circuitry, including BIST circuitry.

Within the core 105, the objects 115 may generally be of any type, designed by the FPOA maker to have any feasible size, architecture, capabilities, and features. Some specific examples of object types include arithmetic logic units (ALUs) 116, multiply accumulators (MACs) 117, and memory banks such as register files (RFs) 118. In brief, a typical ALU 116 may perform logical and/or mathematical functions and may provide general purpose truth functions for control, a typical MAC 117 may perform multiply operations and include an accumulator for results, and a typical RF 118 contains memory that can be utilized as, for example, RAM (random access memory), a FIFO (first-in first-out) structure, or as a sequential read object. For example, one version of an ALU 116 may have a 16-bit data word length, one version of a MAC 117 may operate on 16-bit multiplicands and have a 40-bit accumulator, and one version of a RF may have 0.16 KB (kilobytes) of memory organized as 64 20-bit words. For purposes of the BIST techniques described herein, the internal construction and operational capabilities of the objects 115 are arbitrary.

The size of an FPOA and the number of objects 115 is also arbitrary (within realistic constraints for semiconductor manufacturing). The example FPOA 100, as illustrated in FIG. 1, includes four hundred objects 115 (two hundred fifty-six ALUs 116, sixty-four MACs 117, and eighty RFs 118) organized into a twenty-by-twenty array. However, other FPOAs may have more or less objects 115 (e.g., twenty-by-thirty, thirty-by-thirty, etc.), may include a different mix of objects 115, including objects 115 other than ALUs, MACs, and RFs.

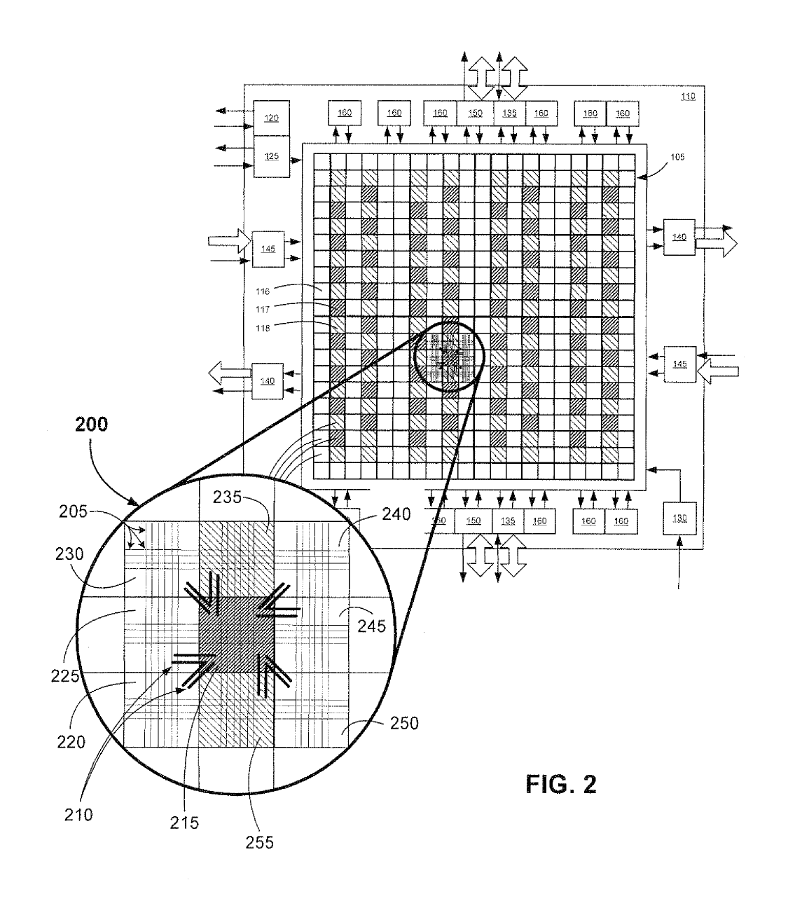

The objects 115 may communicate with each other and/or the periphery region 110 by various methods. For example, two forms of communication mechanisms are (1) nearest neighbor communication and (2) party line communication. A nearest neighbor communication mechanism allows a core object 115 to communicate with one or more of its immediate neighbors. A party line communication mechanism allows an object 115 to communicate with other objects 115 at greater distances and with objects in the periphery region 110. Examples of such communication mechanisms will be described in more detail with respect to FIGS. 2, 3, 4, and 5.

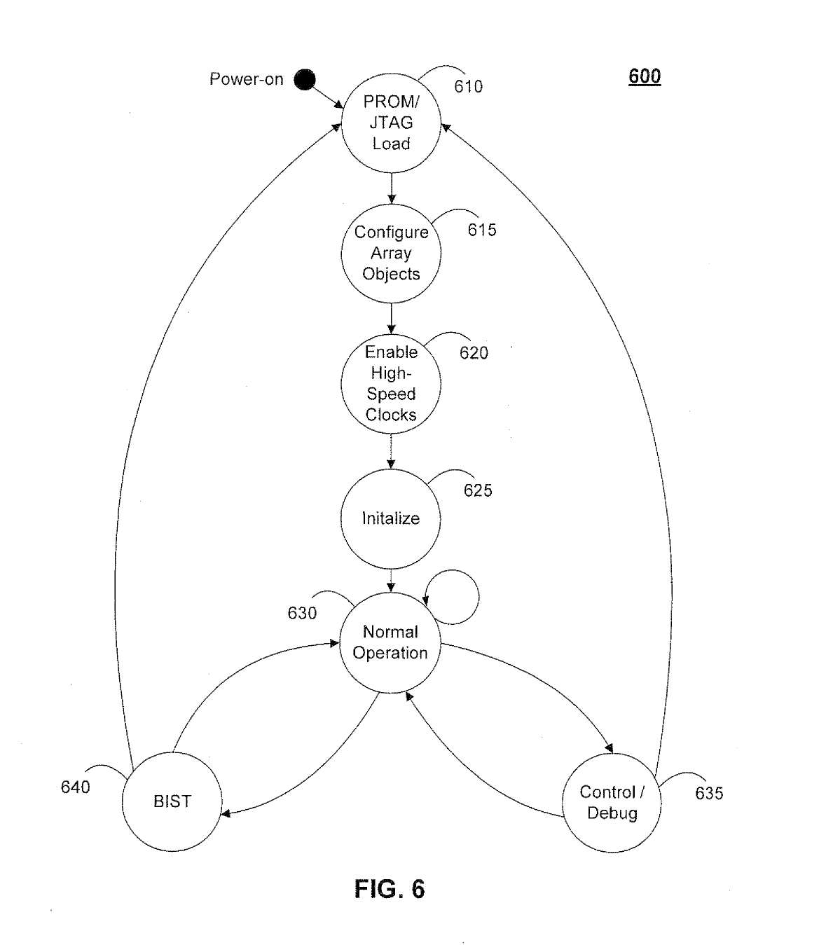

An FPOA can include—typically in its periphery or non-core region—various interfaces used for initialization and control of the array and/or other parts of the device. For example, the FPOA 100 includes a Joint Test Action Group (JTAG) controller 120, which can provide access to a set of registers for controlling the FPOA 100, and a PROM (programmable read-only memory) controller 125, which can oversee the FPOA 100's loading and initialization process. In case a PROM is not present or does not contain valid initialization instructions and/or data, the JTAG controller 120 may also initialize the FPOA 100. If a PROM is present, a PROM controller 125 can oversee the FPOA 100's loading and initialization process (an example of which will be described in more detail with reference to FIG. 6). The FPOA 100 also includes a control object 130, which essentially functions as a shut-off switch by allowing a core clock of the FPOA 100 to be stopped or disconnected.

An FPOA can also include—also typically in its periphery or non-core region—a number of interfaces for communicating with external devices. For example, the FPOA 100 includes two general purpose input/output (GPIO) objects or interfaces 135 (located on the north and south side of the FPOA 100), each of which can provide and/or interface to bidirectional I/O lines or pins, allowing data transfer between the FPOA 100 and external devices. As another example, four high speed interfaces can also be provided on the east and west side of the FPOA 100: two transmit (TX) interfaces 140 and two receive (RX) interfaces 145. The interfaces may operate according to a protocol, such as, for example, parallel low-voltage differential signaling (LVDS). A greater or lesser number of I/O interfaces can be provided in different versions of FPOAs. In addition, other types of I/O interfaces may be provided, such as PCI-e, XAUI, and others.

An FPOA may also include memory and/or memory interfaces in its non-core region. By way of example, the example FPOA 100 comprises XRAM (external RAM) interfaces 150 and IRAM (internal RAM) in its periphery region 110. The XRAM interfaces 150 can provide access to external memory, which may be potentially large in capacity (e.g., 16 meg (16×10⁶) by 72-bit of data accessible via the RLDRAM-II protocol). The IRAM 160 may be a bank of on-chip memory (e.g., single port 2K (2048) by 76-bit SRAM), which can be preloaded during initialization. Thus, the FPOA 100 had three groups of memory: (1) the RFs 118 (assuming such objects are included in the core 105); (2) the XRAM 150; and (3) the IRAM 160.

### Interconnect Framework

FIG. 2 illustrates examples of party line communication channels 205 and nearest neighbor communication channels 210 with respect to a subset 200 of nine objects in the example FPOA 100. A center object 215 may communicate with any of its eight nearest neighbors (i.e., objects 220, 225, 230, 235, 240, 245, 250, or 255) via any of the eight nearest neighbor communication channels 210. The center object 215 may also communicate with any of its eight nearest neighbors, any other object in the array, or any of the objects in the periphery region 110 using one or more of the party line communication channels 205.

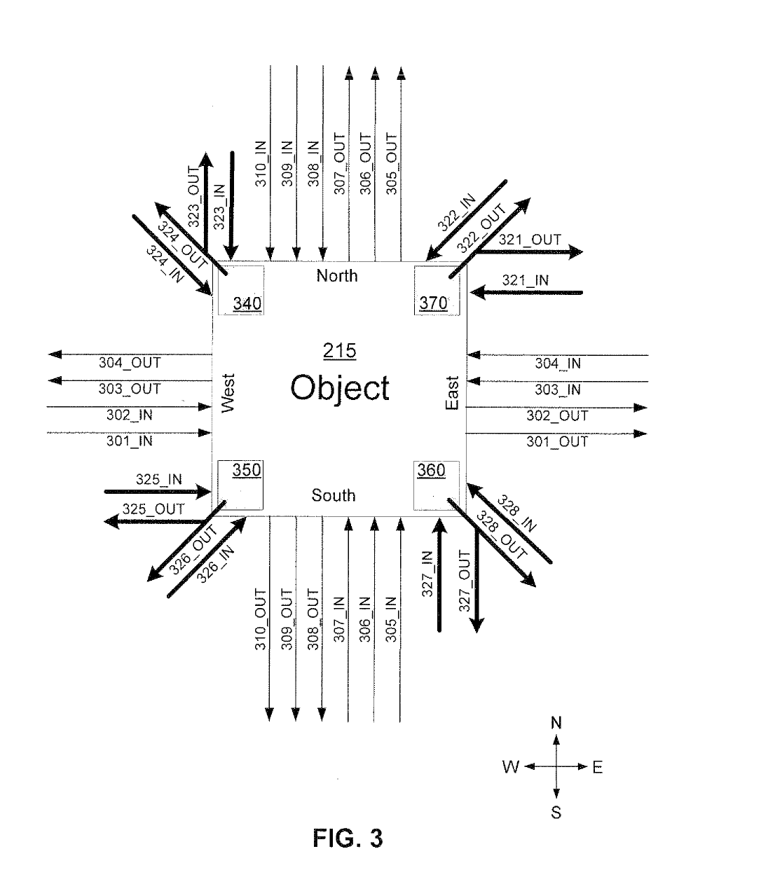

FIG. 3 is a block diagram illustrating in greater detail the communication channels for the object 215. By way of example, as shown in FIG. 3, the object 215 includes a number (e.g., eight) of nearest neighbor communication channels 321-328 and a number (e.g., ten) of party line communication channels 301-310. Of course, an object may have fewer or additional communication channels of either type. The object 215 includes two party line communication channels heading east (301 and 302), two party line communication channels heading west (303 and 304), three party line communication channels heading north (305, 306, and 307), and three party line communication channels heading south (308, 309, and 310). In general, other directional allocations of a given number of party line communications are possible. Party line communications is typically constrained such that data can travel on a party line communication channels through only a certain number of objects per clock cycle (i.e., the data can move a fixed number hops per clock cycle). Four example, the limit may be four hops in one clock cycle before the data needs to land in an internal register of an object and be re-launched on the next clock cycle. If the clock operates at slower speed, the data may move further in one clock cycle. Of course, other embodiments may be designed to move data further than four hops at full speed.

The example object 215 also includes four nearest neighbor registers 340, 350, 360, and 370, each of which may provide data to two adjacent objects via the appropriate pair of nearest neighbor communication channels 321-328. For example, an object directly to the east of object 215 may pull data from register 370 via the nearest neighbor communication channel 321_OUT. Likewise, an object to the northeast of object 215 may pull data from register 370 via the nearest neighbor communication channel 322_OUT. In a similar vein, the object 215 may pull data from the nearest neighbor registers of each of its eight adjacent neighbors. For example, the object 215 may pull data from the southwest nearest neighbor register of an object that is northeast of the object 215 via the nearest neighbor communication channel 322_IN. Likewise, the object 215 may pull data from the southwest (or northwest) nearest neighbor register of an object that is northeast (or east) of the object 215 via the nearest neighbor communication channel 321_IN.

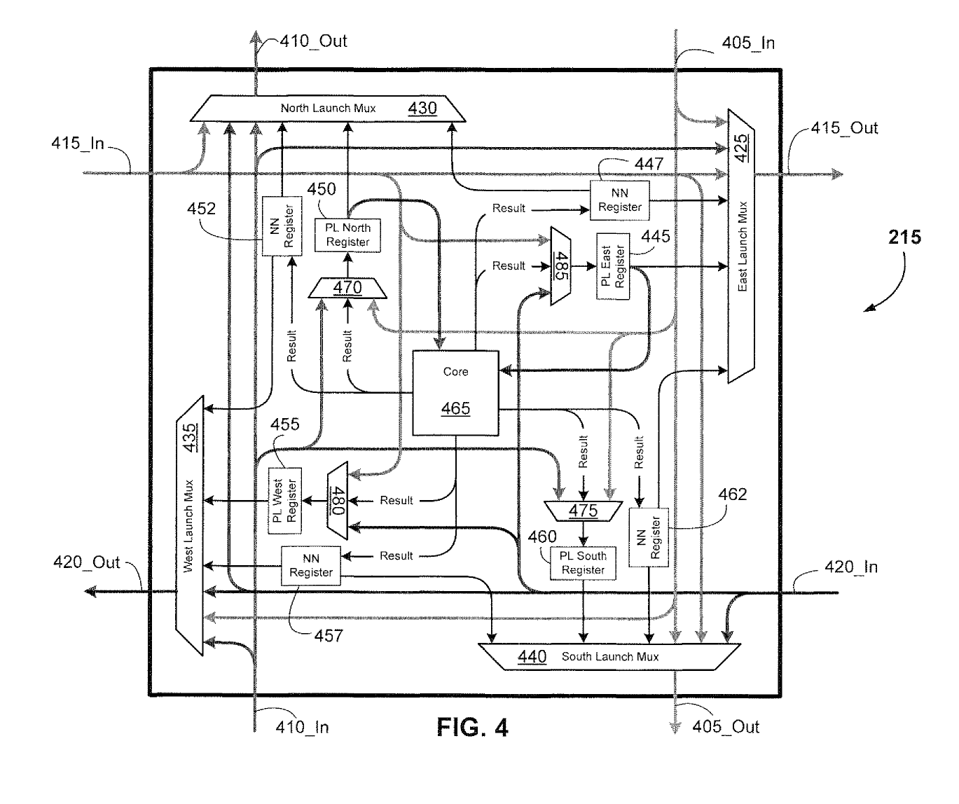

FIG. 4 is a high level logic block diagram illustrating one example of an implementation of the party line communication channels in the example object 215. FIG. 4 illustrates various registers and multiplexers utilized in this example implementation. The ten party line communication channels 301-310 described with respect to FIG. 3 can be divided into three groups: (1) a first group of channels heading north, south, east, and west; (2) a second group of channels heading north, south, east, and west; and (3) a third group of channels heading north and south. FIG. 4 illustrates both the first and second group of party line communication channels (i.e., one heading south 405, north 410, east 415, and west 420). The third group of party line communication channels would be represented by a schematic diagram similar to that illustrated in FIG. 4, but without the party line communication channels heading east and west.

In one example implementation, the party line communication channels are implemented as unidirectional segmented buses. Such a bus is segmented in the sense that it passes through some logic circuitry (e.g., one of the launch multiplexers 425, 430, 435, or 440) and/or a register (e.g., one of the party line registers 445, 450, 455, or 460) along the way from one bus segment to the next bus segment.

With respect to the example implementation illustrated in FIG. 4, the party line communication channels within the object 215 may be configured in several ways. For example, the object 215 may be configured to selectively “pass” a value received from a previous object (i.e., an object from the north) on the party line communication channel 405_IN to a next segment (i.e., the party line communication channel 405_OUT) via the south launch multiplexer 440. The object 215 may also be configured to “turn” the value from the previous object to a different party line communication channel. For example, data on the party line communication channel 405_IN may turn onto party line communication channel 415_OUT via the east launch multiplexer 425. Likewise, data on the party line communication channel 405_IN may turn onto party line communication channel 420_OUT via the west launch multiplexer 435.

The object 215 may also be configured to “land” data from a previous object on a bus into one of its party line registers 445, 450, 455, or 460. For example, a value on the party line communication channel 405_IN may be stored in the north party line register 450 via the north party line multiplexer 470 and/or stored in the south party line register 460 via the south party line multiplexer 475. As shown, the north party line register 450 may also store values from the core 465 and/or from the party line communication channel 410_IN via the north party line multiplexer 470. Likewise, the south party line register 460 may also store values from the core 465 and/or from the party line communication channel 410_IN via the south party line multiplexer 475.

The object 215 may “launch” values to another object via various party line communication channels and the launching multiplexers 425, 430, 435, and 440. For example, the south launching multiplexer 440 can launch data from the south party line register 460, nearest neighbor registers 457 and 462, or the party line communication channels 405_IN, 415_IN, and 420_IN. Likewise, the north launching multiplexer 430 can launch data from the north party line register 450, nearest neighbor registers 447 and 452, or the party line communication channels 410_IN, 415_IN, and 420_IN.

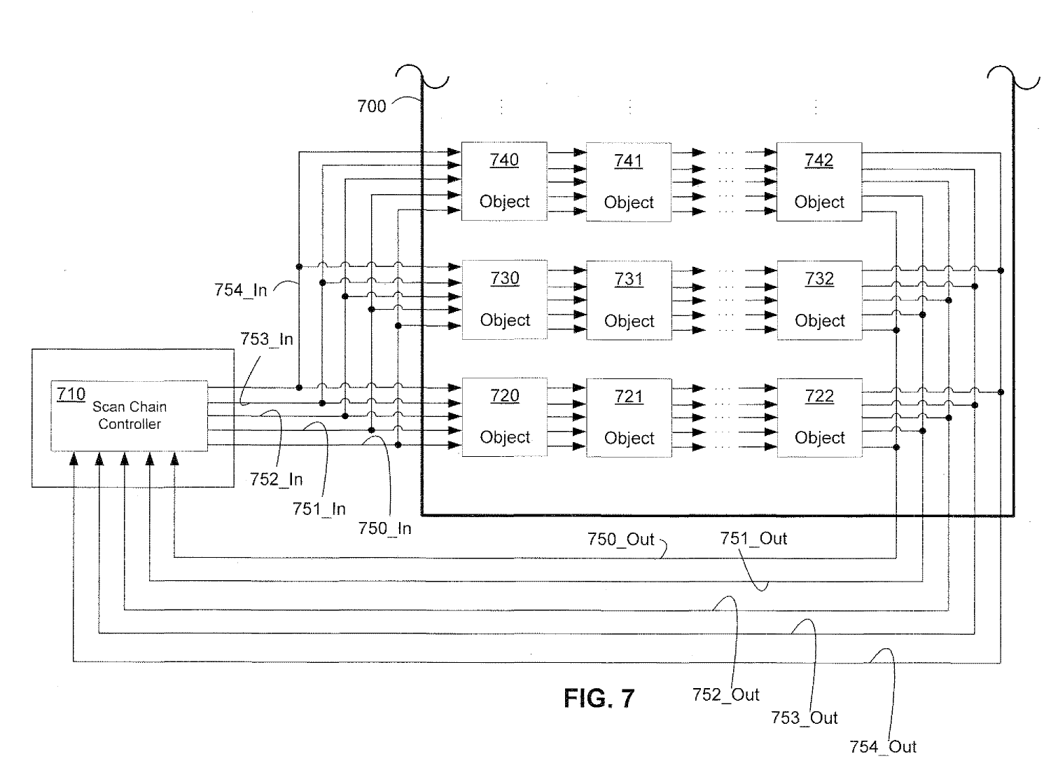

Each multiplexer 425, 430, 435, 440, 470, 475, 480, and 485 has a selector (e.g., a select input) to control which of the input signals (e.g., 410_IN, 415_IN, etc.) will be used as the output signal (e.g., 410_OUT). Thus, the party line communication channels are controlled by the selectors of the multiplexers. The selector can be set to a static position when the object is initialized or it can be controlled dynamically during runtime. The configuration and initialization of the object will be described in more detail with respect to FIGS. 6 and 7. Although not specifically described, the operation of the party line communication channels heading east and west (i.e., 415 and 420) operate in a similar manner. A more detailed discussion of an unidirectional segmented bus architecture is provided in commonly owned U.S. Pat. No. 6,816,562, issued Nov. 9, 2004, entitled “Silicon Object Array With Unidirectional Segmented Bus Architecture,” which is incorporated herein by reference in its entirety.

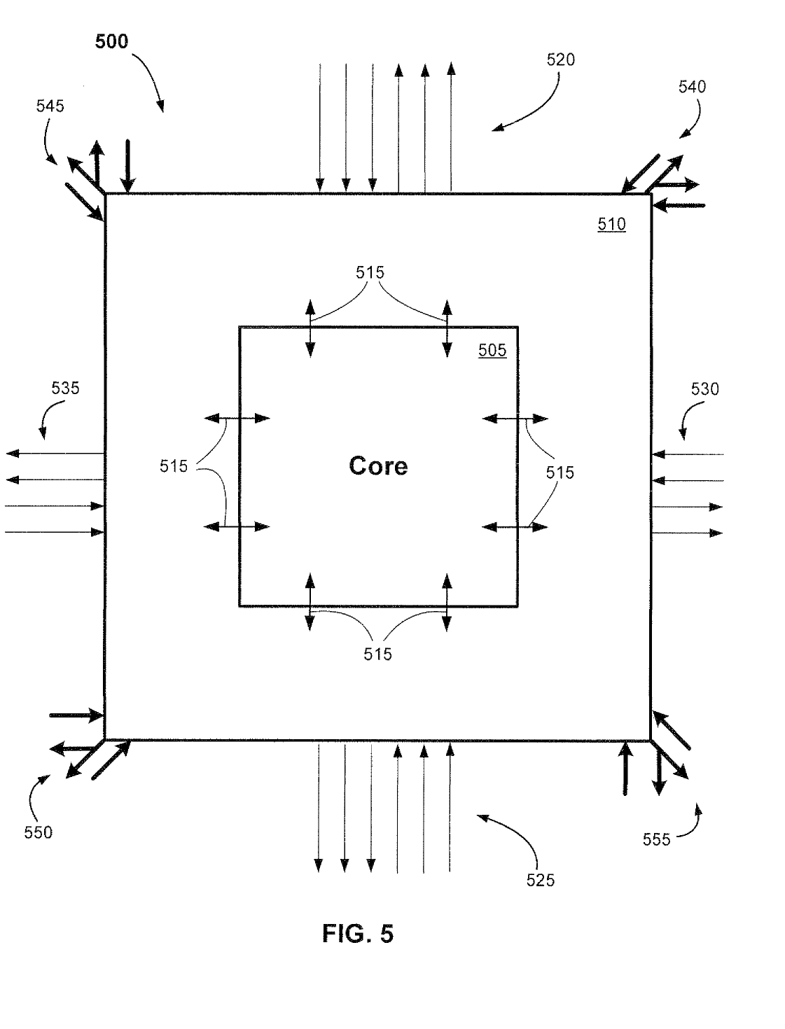

As shown in FIG. 5, an object 500 can be abstracted into an internal functional object core 505 and a communications infrastructure 510. The object core 505 contains the internal functional circuitry specific to that type of object (e.g., ALU, MAC, RF, or other). The communication infrastructure 510 contains the inter-object communication circuitry (which can also enable communication with the non-core region of the FPOA), such as, for example, party line communication channels 520, 525, 530, and 535 and/or nearest neighbor communication channels 540, 545, 550, and 555—which may be as described above. The core 505 and the communication infrastructure 510 can be communicatively coupled to one another via one or more interconnections 515. The communication infrastructure 510 may be the same or similar for diverse objects, with the possible exception of its interfaces to the interconnections 515, which typically are unique to the particular object core 505.

### Power Control

With continued reference to FIG. 5, a power bus, grid or line (not shown; referred to for convenience and without loss of generality as a “power bus” herein) supplies power to the core 505 and the communications infrastructure 510. The power bus may be implemented as a conductive layer that overlays the object 500 as well as other objects in the FPOA's core region and non-core region (e.g., the core region 105 and the periphery region 110 of the example FPOA 100 illustrated in FIG. 1). Alternatively, the power bus may be implemented in other ways, such as one or more conductive traces that snake through the object 500 and other objects in the FPOA core region and non-core region.

The components that make up the core 505 and communications infrastructure 510 may be selectively connected to the power bus. For example, one or more transistors may be dedicated to connecting or disconnecting the various components within the core 505 and communications infrastructure 510 to the power bus. Selectively coupling the logic core 505 and communications infrastructure 510 to the power bus allows one or the other or both to be powered up or down in any desired combination. For example, the logic core 505 may be powered up when it is needed to perform functions and powered down when not in use. By way of another example, any combination of the party line communication channels 520, 525, 530, and 535 may be powered up when needed to relay data to other objects. Thus, the object 500 may have both its core 505 and party line communication channels 520, 525, 530, and 535 powered down when not in use and powered up when in use. As another possibility, the object 500 may have its logic core 505 powered down but have the north and south party line communication channels 520 and 525 powered up to allow objects to the north and south of the object 500 to pass data through the object 500. Further, the object 500 may have its core 505 powered down but have the east and west party line communication channels 530 and 535 powered up to allow objects to the east and west of the object 500 to pass data through the object 500.

Powering up or down the core 505 and communications infrastructure 510 may be accomplished in other ways. For example, the logic core 505 and communications infrastructure 510 may be selectively disconnected from power rails or a ground bus (or ground plane). Further, the clock(s) driving the core 505 and the communications infrastructure 510 may be selectively gated, slowed, or disconnected. For example, if only the communications infrastructure 510 is needed, the clock driving the communications infrastructure 510 may be activated while the clock driving the core 505 may be deactivated. This effectively prevents portions of the circuitry from changing states.

FIG. 6 is a high-level state transition diagram 600, illustrating an example of operational states and flow for an FPOA (e.g., the example FPOA 100 illustrated in FIG. 1). When the FPOA is powered on, the FPOA enters a loading state 610, wherein, according to this example, the FPOA checks whether a PROM is present and if so, accesses the PROM to acquire configuration information. If there is no PROM present, the FPOA waits for the configuration information via an interface, such as a JTAG interface, PCI-e interface, or other interface.

Next, in a configuration state 615, the objects within the FPOA are configured. According to one example, a scan chain controller (as will be discussed in more detail with respect to FIG. 7) can be used to do the configuration by shifting configuration information into the objects via one or more scan chains. To simplify timing and synchronization, the objects, which normally operate in a high-speed domain, may not be coupled to a high-speed clock until after configuration.

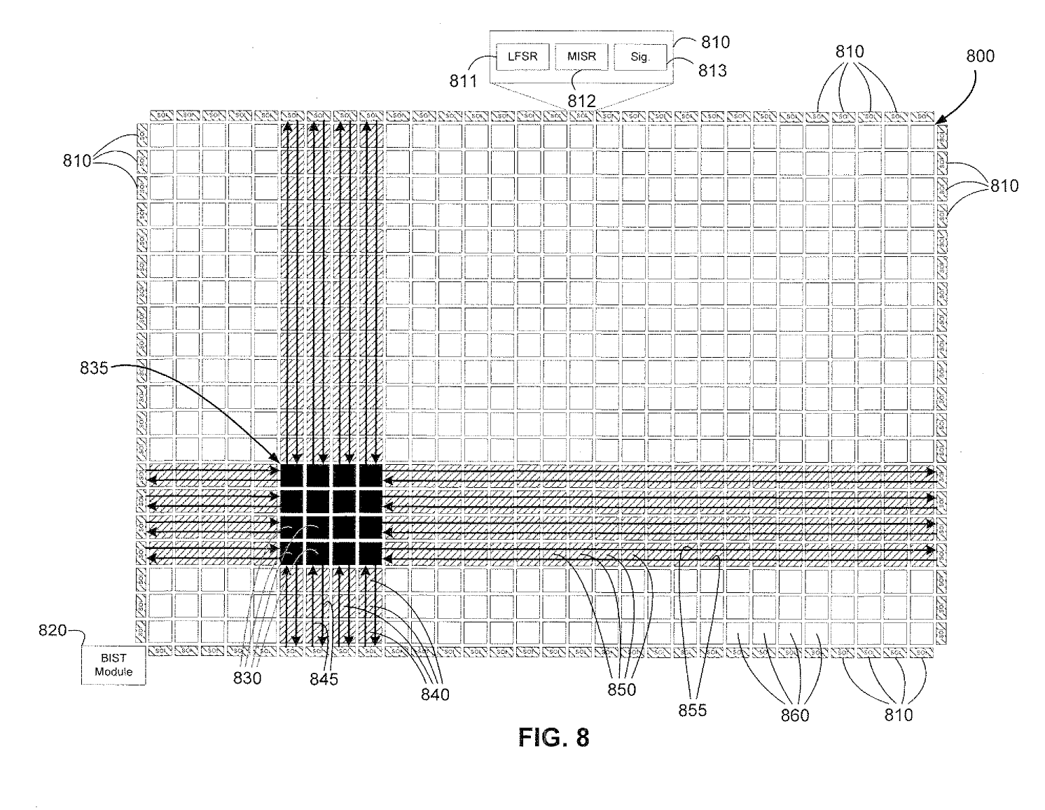

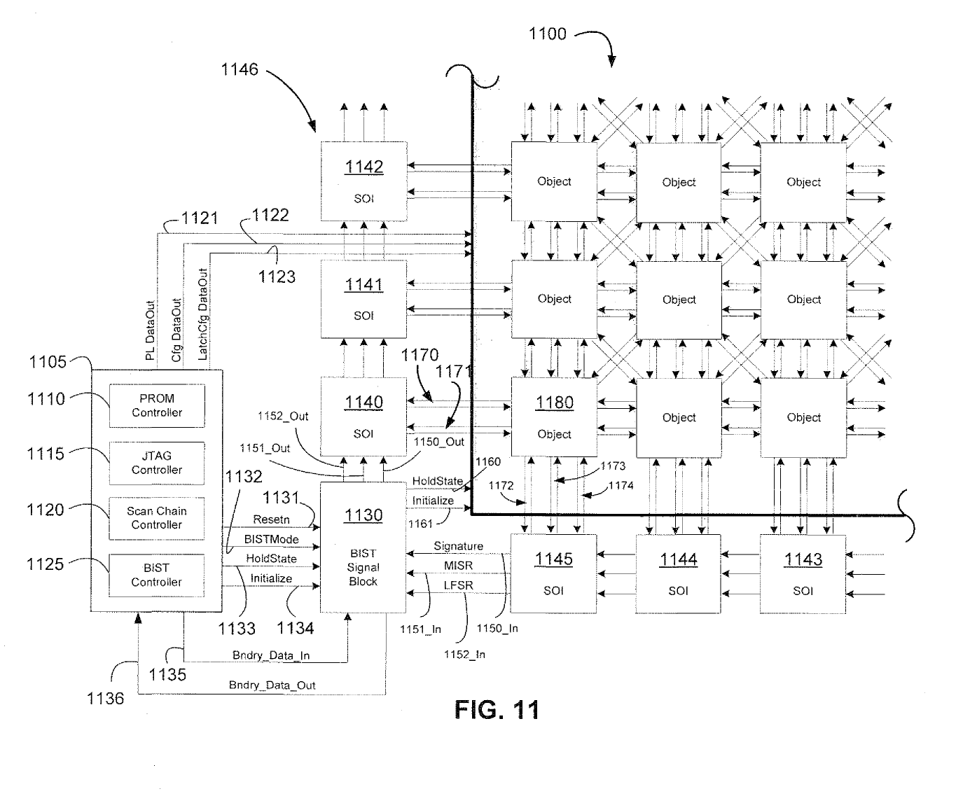

After the configuration information has been loaded, the objects operating in the high-speed domain are coupled to the high-speed clock in state 620, and the objects are initialized in state 625. A current surge may occur at step 620 due to the activation of dynamic logic within the objects. For example, current surges up to approximately 50 amperes within a nanosecond are possible. To help reduce the current surge, the objects are set to a predetermined default state at step 625. For example, the predetermined default state may be configured to reduce the number of state changes within the object (e.g., reduce the number of toggling signals). After the power supply has stabilized from the sudden current inrush, the FPOA can begin executing its application in its normal operation state 630 (e.g., by clearing an initialize signal). Another large current surge may occur as the objects transition from their default state (e.g., data paths stable) to their running state. The FPOA remains in the normal operation state until dislodged from that state, such as, for example, when a JTAG controller (see FIG. 11) or BIST controller (see FIGS. 8, 11, 12, and 15) assumes control of the FPOA.

In a control or debugging state 635, a JTAG controller can pause the operation of the FPOA at any point during normal operation. This may allow, for example, the internal status of any objects within the FPOA to be observed. After the JTAG controller has completed its operation, the FPOA may be returned to its normal operation (i.e., to the normal operational state 630) or reset (i.e. to the loading state 610).

As will be described in more detail with respect to FIGS. 8-12, and 15, a BIST controller may also assume control over the FPOA to exercise circuits within the objects operating in the high-speed domain. For example, the BIST controller may alter the configuration of the objects within the array, stimulate a selected subset of objects with a input test pattern, and observe the response of the selected subset of objects. When the BIST controller is finished, the FPOA may be reloaded at state 610 or may simply be returned to the normal operation state 630.

FIG. 7 illustrates one example of a scan chain controller 710 used to program a plurality of objects 720-722, 730-732, and 740-742 in an FPOA 700. According to this example, each row of objects in the FPOA 700 is communicatively coupled to the scan chain controller 710 via a plurality of scan chains 750-754. The scan chains extend through the FPOA 700, linking the output of one object to the input another object (i.e., the output of object 720 is linked to the input of object 721, the output of object 721 is linked to the input of a next object, and so forth to a last object 722 in the chain). Each scan chain 750-754 may be circular in the sense that data may be shifted in (i.e., 750_IN, 751_IN, 752_IN, 753_IN, and 754_IN) and out (i.e., 750_OUT, 751_OUT, 752_OUT, 753_OUT, and 754_OUT) with each clock cycle. However, as will be described in more detail below, one or more of the scan chains may not be circular (i.e., data can only be shifted into the scan chain).

According to this example, the scan chain controller 710 operates in a low-speed clock domain (i.e., it typically operates at a lower clock speed than the operational-speed of the objects). As used herein, the terms “low-speed” and “high-speed” simply mean lower and higher than each other, respectively, without implying any numerical values or ranges of values. By way of example and not limitation, the scan chain controller 710 may operate at approximately 50 MHz (megaHertz or one million cycles per second) or less, whereas the objects are designed to operate at approximately 1 GHz (gigaHertz or one billion cycles per seconds). Of course, the scan chain controller 710 and the objects may operate at other clock speeds. For example, the scan chain controller 710 may also operate in the high-speed clock domain and may control other high-speed and/or low-speed scan chains. In addition, scan chain configurations other than those shown in FIG. 7 are possible. For example, the scan chains may be addressed to control the destination scan chain for each bit of data. Furthermore, there may be fewer or additional scan chains. For example, one scan chain may snake through all of the objects. By way of another example, the scan chains may run up or down each column instead of across each row. Further, each object may be individually connected to the scan chain controller 710.

According to one example, three sets of scan chains are utilized: (1) two party line scan chains (e.g., scan chains 750 and 751); (2) two configuration scan chains (e.g., scan chains 752 and 753); and (3) one latch scan chain (e.g., scan chain 754). As previously mentioned, certain scan chains may not be readable. For example, the latch scan chain 754 may only have a scan chain input 754_IN, but no scan chain output 754_OUT.

The party line scan chains 750 and 751 may be used to configure how each object interacts with the party line communication channels. For example, the party line scan chains 750 and 751 may control the selector of each multiplexer in the object to dictate which of the input signals will be used as an output signal (refer to FIG. 4). By manipulating the selectors, the party line scan chains can effectively tell an object to, for example, pass data from east to west and/or to pass data from one of its nearest neighbor registers to a northbound party line. By using two party line scan chains 750 and 751, data may be shifted in more quickly. Accordingly, fewer or additional scan chains may be used to configure the party line communication channels.

The configuration scan chains 752 and 753 may be used to configure the primary or core functionality of objects. For example, internal registers, counters, instructions, addresses, and the like can be programmed or set in this way. Again, by using two configuration scan chains 752 and 753, data may be shifted in more quickly. Accordingly, fewer or additional scan chains may be used to configure the primary functionality of object. Finally, the latch scan chain 754 may be used to configure any memories within the objects. Additional scan chains may be used to configure object memories.

Of course, a FPOA may utilize additional or fewer scan chains to program objects in the core region. Further, one or more scan chains may be used to program logic in the non-core region, such as the I/O interfaces, memory interfaces, and memory. By way of example, a scan chain circling the periphery of the FPOA may be used to program the I/O interface.

The description of FIGS. 1 through 7 has provided an overview of a few examples of FPOA architectures and associated concepts. Other examples are possible. Other examples and additional details regarding FPOAs may be found in the following commonly owned United States patent applications, which are incorporated by reference herein in their entireties: application Ser. No. 11/042,547, filed Jan. 25, 2005, entitled “Integrated Circuit Layout Having Rectilinear Structure of Objects” (published as no. 2006/0080632 on Apr. 13, 2006); and application Ser. No. 11/567,146, filed Dec. 5, 2006, entitled “Field Programmable Semiconductor Object Array Integrated Circuit” (published as no. 2007/0247189 on Oct. 25, 2007). Moreover, additional discussion of FPOA concepts may be found in the “Arrix Family FPOA Architecture Guide” dated May 18, 2007 and the “Arrix Family Data Sheet & Design Guide” dated May 22, 2007, both of which are published by MathStar, Inc., Hillsboro, Oreg. In light of the teachings herein, those skilled in the art will be aware of equivalent architectures, implementations, variations, etc. for FPOAs.

### Built-In Self-Testing

Built-in self-testing an FPOA may be accomplished in various ways, as described in this subsection.

According to one embodiment, built-in self-testing of an FPOA proceeds by testing a subset of objects at one time. The subset of objects-under-test may be a single object or all objects but is typically less than all objects (i.e., a proper subset) and most typically a small number of objects. In that case, comprehensive testing of all objects to some extent (but not necessarily to the full extent of an individual object's capabilities) can be achieved by serially testing different subsets until all subsets have undergone testing.

Before describing details of testing approaches at the subset level or the array level, the concept of subsets will be explained further. The case of a regular rectilinear array of objects 800 is illustrated in FIG. 8. In that case, one choice of a subset of objects-under-test is a set of contiguous objects in a rectangle-shaped pattern. An example of such a subset 835, which is a four-by-four rectangle, is illustrated in FIG. 8 and can be referred to as a “rectangle-under-test” or its acronym “RUT.” RUTs of other sizes and shapes are possible. For example, a RUT may be a single object, an eight-by-eight set, a four-by-eight set, a two-by-six set, etc., all or part of a single row, or all or part of a single column.

Before or after the objects 830 in the RUT 835 have been tested, all or most of the other objects in the array 800 may be tested by iteratively testing new RUTs or other subsets of objects. For example, a RUT of the same size and shape may start in the lower left hand portion of the core region of the array and iteratively march right in steps of one column or greater. The size of the step is preferably less than the size of the RUT in the east-west direction for comprehensive coverage of all objects. After the RUT reaches the right most column, the RUT may be moved up one or more rows, and the right-marching process repeated until all or most of the objects have been tested at least once. The size of the RUT may be altered during the test or from test to test. For example, a large RUT may be used to test the number of hops data can move in one clock cycle. Indeed, the RUT may have a square, rectangular, or other geometric shape or may comprise one or more entire columns or rows.

Also shown in FIG. 8 are a plurality of object interfaces 810, which are sometimes called “silicon object interfaces” or “SOIs,” although it should be understood that the FPOA may not be made of silicon. The FPOA may be made of another semiconductor such as gallium arsenide or any other suitable material. The acronym SOI will be used herein as a convenient shorthand and without loss of generality with respect to the material making up the FPOA and without implying limitation to silicon. The SOIs 810 surround the objects 800 to enable communication between the objects 800 and other components of the FPOA. As shown, each SOI is associated with a row or column of objects 800. The SOI may communicate with the objects by, for example, interfacing with one or more party lines traversing that row or column. As compared to the objects 800, which are located in a central portion of the integrated circuit according to the example layout depicted in FIG. 8, the SOIs 810 may be located in an area of the integrated circuit peripheral to the central portion, as shown.

The SOIs 810 may also enable the objects 800 to communicate with, for example, a BIST module 820, as shown in FIG. 8. In one embodiment, the BIST module 820 controls and oversees the overall testing of the objects 800. For example, the BIST module 820 may: (1) control the programming of the objects 800; (2) determine whether the objects 800 should operate at full speed or whether the objects 800 should idle; (3) initiate the stimulation of the RUT 835 with a pseudo-random input pattern; and (4) observe a response of the RUT 835 to the applied stimulus.

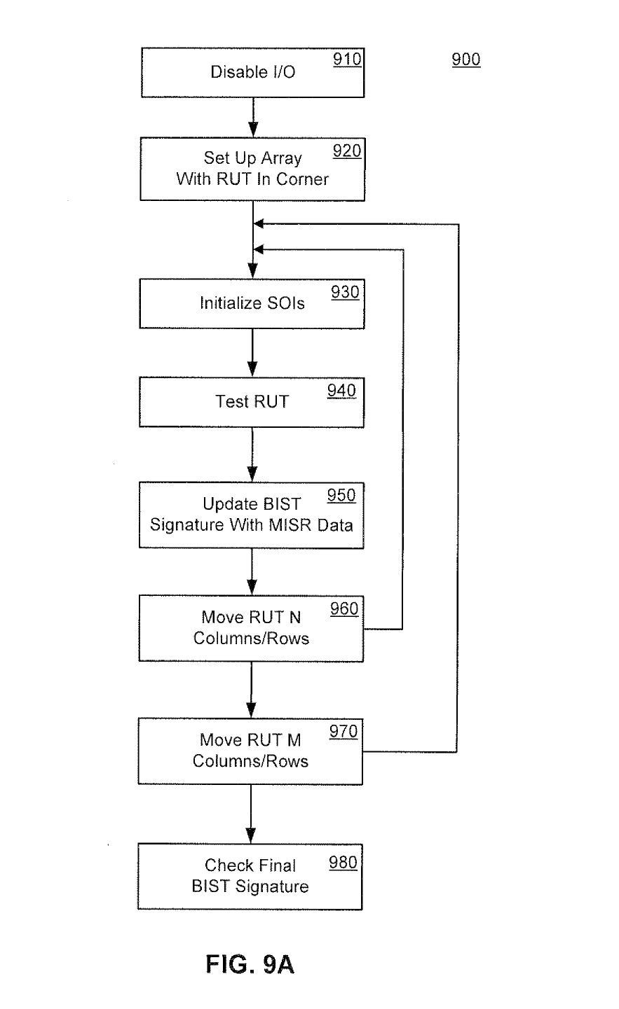

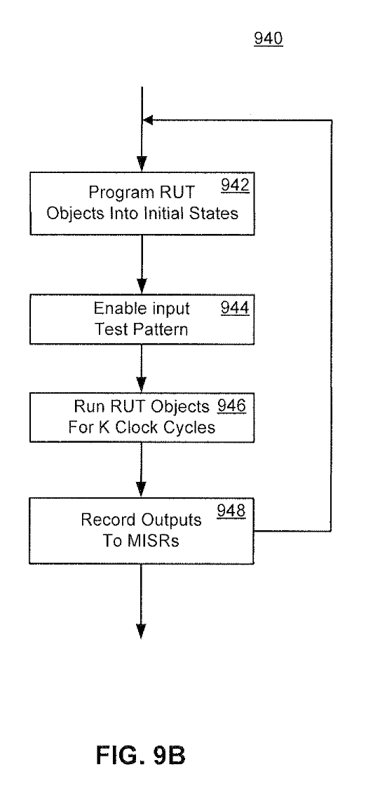

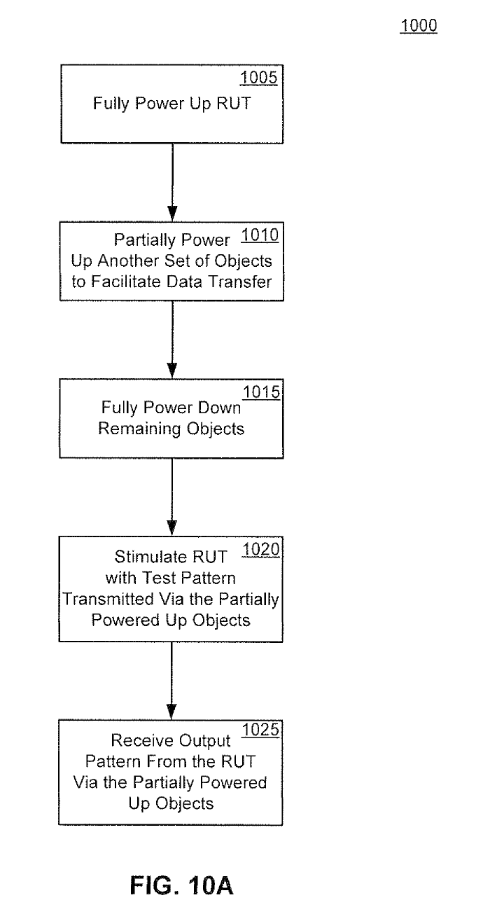

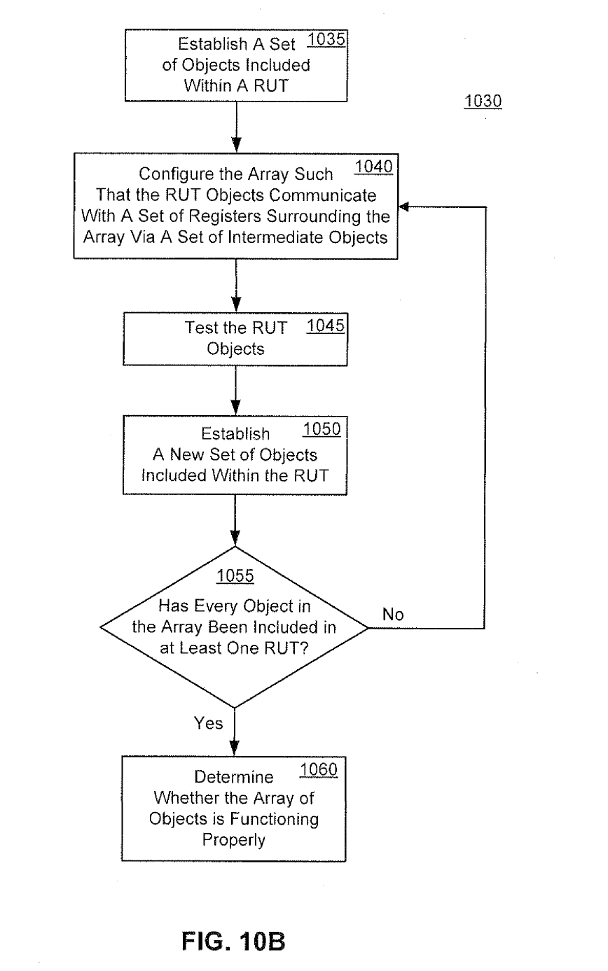

The BIST module 820 may program the objects 800 such that some or all of the objects 830 in the RUT 835 are fully powered up, other objects 840 are partially powered up to enable the north/south party line communication, other objects 850 are partially powered up to enable the east/west party line communication, and yet other objects 860 are fully powered down. The objects 830 collectively define the objects to be tested (i.e., the RUT 835). The objects 840 collectively define the north and south communication channels 845 that allow communication between the RUT 835 and the SOIs 810 to the north and south of RUT 835. Likewise, the objects 850 collectively define the east and west communication channels 855 that allow communication between the RUT 835 and SOIs 810 to the east and west of RUT 835. Fully powering down the remaining objects (i.e., objects 860) may help limit the total power consumption of the array and help prevent a large current inrush. As will be described in more detail with respect to FIGS. 9 and 10, the BIST module 820 may control the programming of the objects 800 by commandeering the scan chain controller 710 (FIG. 7).

After programming the objects 800, the BIST module 820 may tell some or all of the objects to run at full speed for a certain number of clock cycles. For example, the objects 830, 840, and 850 may be coupled to the high-speed clock and initialized so that one or more test patterns may be transmitted to the objects 830 (i.e., RUT 835) via objects 840 and/or 850 and one or more output patterns generated by objects 830 may be carried away via objects 840 and/or 850. The test patterns may be generated, for example, by linear feedback shift registers (LFSRs) 811 within the SOIs 810 and the output patterns may be received by, for example, multiple-input shift registers (MISRs) 812 within the SOIs 810. The MISRs 812 may compress the output patterns into a signature register 813, which may also be located within the SOIs 810. As will be described in more detail below, after the objects 800 have been tested, a final signature may be obtained by serially shifting the data within each signature register 813 out of the SOIs 810 and into the BIST module 820. If the final signature matches an expected value, the FPOA is likely operating as designed.

FIG. 9A is a flowchart of an overall array-level BIST method 900, according to one embodiment. The method 900 first disables (step 910) I/O to/from the FPOA so that signals at the device's pins do not disrupt circuits and devices that may be connected to the FPOA device. For example, the method 900 may utilize a I/O interface scan chain that circles the periphery of the FPOA to disable the I/O.

The method 900 then sets up (step 920) the array with the RUT in an initial position, such as one corner of the array. In doing so, the method 900 fully or partially powers up or down array objects as desired, such as described above in relation to FIG. 8. Next, the method 900 initializes (step 930) the interfaces in the non-core region. For example, for the example layout illustrated in FIG. 8, the method initializes the SOIs 810, in particular by loading a known seed into the LFSRs 811, by clearing or otherwise initializing the MISRs 812 and the intermediate signature registers 813. Thereafter, the method 900 tests (step 940) the RUT. The RUT-testing step 940 is described in greater detail with reference to FIG. 9B. After completion of testing of the RUT, the method 900 updates (step 950) the final BIST signature based on the contents of the MISRs 812. Then, the method 900 moves the RUT N (N≧1) columns or rows (depending on the direction of movement) and sets up the array so as to establish the RUT in its new position. The method 900 repeats the steps 930-950 at the new RUT position. The steps 930-960 are repeated until the RUT has moved entirely across one dimension of the array (either east-west or north-south). When a pass in one direction is complete, the method moves (step 970) the RUT M (M≧1) rows or columns (the other one from step 960) in the array to set up the RUT on one side (either side) of a different portion of the array. In that new position, the method 900 repeats steps 930-960 to test various RUTs across that swath of the array. The method 900 repeats steps 930-970 for a number of swaths, preferably until every object has been part of at least one RUT. While the RUT may stay completely within the array, the RUT may be partially outside of the array in certain test positions. For instance, a four object wide RUT may have 23 positions in which all or part of the RUT resides within a 20 object wide array instead of 17 positions in which all of the RUT resides within the 20 object wide array.

Finally, the method 900 checks (step 980) the final BIST signature, which has been updated all along, by, for example, comparing it to a known good result to decide whether the FPOA has passed or failed BIST testing. The known good result may be based on a simulation. In addition, the known good result may be based on empirical data. For example, after performing the same method 900 on a plurality of different FPOAs, an identical final BIST signature may be observed multiple times. The identical final BIST signature may be adopted as the known good result and be used to make subsequent pass/fail determinations.

FIG. 9B is a flowchart of the RUT-testing step 940 in greater detail. This step begins by programming (step 942) all or some of the objects in the RUT into an initial state and enabling (step 944) an input test pattern to stimulate the RUT. Both the initial state and the input test pattern are chosen such that they test the RUT to a desired statistical level of confidence. In one embodiment, both the initial states and the input test patterns are known but pseudorandom, such as generated by an LFSR configured to generate maximal-length or M-sequences. Different initial states of the objects can configure different communication paths via the settings of such things as multiplexer selectors. The steps 942 and 944 may be performed in either order or simultaneously.

Next, the method 900 runs (step 946) the RUTS (and any other powered or partially powered objects outside the RUT) for a number (K) of clock cycles. Preferably, step 946 occurs at the operational (e.g., “high”) clock speed at which the objects would operate during non-testing operation. In other words, the testing at this step is performed in the high-speed clock domain. The other steps of the method 900, by contrast, may be run in the low-speed clock domain. High speed BIST testing of the objects per se is possible because the objects themselves need not be altered to accommodate BIST. That is to say, the design of the objects is not constrained to require within an object extra circuitry not essential to non-testing operation just to facilitate BIST. Rather, the non-essential testing circuitry is in the non-core (e.g., periphery) region of the array, which may operate in the low-speed clock domain without causing operational performance penalty.

After the K clock cycles complete, the method 900 records (step 948) the outputs of the RUT objects, such as in the MISRs of the SOIs to which the RUT objects are linked. The steps 942-948 can thereafter be repeated a configurable number of times. An advantage of repeating the steps under varied configurations, set-up or initial conditions and/or varied input test patterns is an increase in the coverage of possible modes, states, and operational scenarios being tested, thereby increasing the statistical confidence level of the testing. Using known but random-like configurations and/or input test patterns seems to provide satisfactory variability in the testing conditions.

Many variations of the method 900 or its steps are possible. FIGS. 10A and 10B illustrate some variations and associated methods.

FIG. 11A illustrates a method of configuring and testing a subset of objects according to one embodiment. Once BIST has been initiated, all of the objects within the array are configured into one of three states: (1) fully powered up; (2) partially powered up; and (3) fully powered down. At step 1005, a set of objects to be tested (e.g., the RUT 835) is fully powered up. In one version of this method, fully powering up an object includes powering up an object's core and party line communication channels. For example, the various components that make up the core and party line communication channels may be connected to a power bus, a ground bus, and/or a high-speed clock. According to another embodiment, an object may be fully powered up in a logical sense. For instance, the core may be able to pull data from and/or write data to the party line registers and nearest neighbor registers within the object or one or more of the nearest neighbor registers of adjacent objects (see, e.g., FIG. 3). Likewise, the party line communication channels may be fully functional. For example, the landing multiplexers (e.g., multiplexers 470, 475, 480, and 485 of FIG. 4) may be able store incoming party line data in the party line registers (e.g., registers 445, 450, 455, and 460). In addition, the launching multiplexers (e.g., multiplexers 425, 430, 435, and 440) may be able pass or turn incoming party line data or launch data from the party line registers and/or nearest neighbor registers. Other suitable methods of fully powering up an object may be utilized. For instance, an object may be fully powered up to provide control of the entire “core” functionality as well as specific party line communication channels. In addition, a more fine grain approach to powering up the core may be utilized.

At step 1010, another set of objects is partially powered up to allow party line communication channels to relay data to and from the RUT. According to one embodiment, partially powering up an object involves fully powering up a portion of an object's party line communication channels, while powering down (e.g., gating the clocks) the rest of the party line communication channels and the core. For example, an object that relays data east and west may have its east and west party line communication channels powered up while its north and south party line communication channels and its core are powered down. By way of another example, an object that relays data north and south may have its north and south party line communication channels powered up while its east and west party line communication channels and its core are powered down. Powering up or down the core and the east/west or north/south party line communication channels may involve selectively connecting the various components that make up the core and party line communication channels to a power bus, a ground bus, and/or a high-speed clock.

According to another embodiment, partially powering up an object involves logically turning on a portion of the party line communication channels (e.g., the north/south party line communication channels or east/west party line communication channels) while logically turning off the rest of the party line communication channels and the core. For example, an object that relays data from east to west or west to east may be configured such that the multiplexer 485 (FIG. 4) always places data from line 415_IN into party line east register 445 and east launch multiplexer 425 always launches data from the party line east register 445 onto its output (e.g., 415_OUT). Likewise, multiplexer 480 may always place data from line 420_IN into party line west register 455 and the west launch multiplexer 435 may always launch data from the party line west register 455 onto its output (420_OUT). All of the other multiplexers (e.g., multiplexers 430, 440, 470, and 475) may have an output of logical ‘0’ or ‘1’ regardless of their inputs. This may effectively disable the core 465 and the north/south party line communication channels by preventing them from communicating with other objects. In other words, the core and north/south party lines are logically off.

By way of another example, an object that relays data from north to south or south to north may be configured such that the multiplexer 470 always places data from line 410_IN into party line north register 450 and the north launch multiplexer 430 always launches data from the party line north register 450 onto its output (410_OUT). Likewise, the multiplexer 475 may always place data from line 405_IN into party line south register 460 and the south launch multiplexer 440 may always launch data from the party line south register 460 onto its output (405_OUT). All of the other multiplexers (e.g., 425, 435, 480, and 485) may have a logical output of ‘0’ or ‘1’ regardless of their inputs. This may effectively disable the core 465 and the east/west party line communication channels by preventing them from communicating with other objects. In other words, the core and east/west party line communication channels are logically off.

At step 1015, any remaining objects in the array are preferably fully powered down. According to one embodiment, fully powering down an object includes powering down its core and party line communication channels. For example, the various components that make up the core and party line communication channels may have their clocks gated or may be disconnected from a power bus, a ground bus, and/or a high-speed clock. According to another embodiment, an object may be configured such that it is communicatively isolated from other objects. In other words, the four launch multiplexers 425, 430, 435, and 440 could be configured such that their output is always a logical ‘0’ or ‘1’ regardless of its inputs. Even though an object may be powered down, the powered down object may still be configured via one or more scan chains and provide input to the RUT. For example, data shifted into a nearest neighbor register of a powered down object may be pulled from a RUT object during test.

The objects within the array need not be configured into a fully powered up, partially powered up, or fully powered down state in any particular order. In fact, according to one embodiment each object's configuration is shifted in. Thus, all of the objects may be effectively configured together. In other words, the steps 1005, 1010, and 1015 need not be performed in the order shown in FIG. 10A.

At step 1020, the fully powered-up set of objects (e.g., the RUT) is stimulated with a test pattern. For example, one or more LFSRs 811 (FIG. 8) in the SOIs 810 may provide a pseudo-random stimulus to the RUT via the party line communication channels in the objects directly to the north, south, east, and west of the RUT. In other words, the pseudo-random data propagates from the LFSRs 811 to the RUT (e.g., the data may move one object per clock cycle). The objects within the RUT generate output patterns in response to the stimulus. At step 1025, an output pattern is received from the RUT. For example, the output pattern may travel away from the RUT via the partially powered-up set of objects. After a certain number of clock cycles, the output pattern is captured by the MISRs 812. As already noted and as will be described in more detail with respect to FIG. 10B, the steps 1020 and 1025 can be repeated for a number of varied configurations of the objects in the RUT to enhance statistical coverage of the testing. In other words, the objects within the RUT may be reconfigured and tested again before the RUT moves to another location.

FIG. 10B illustrates a method 1030 of testing an FPOA according to another embodiment. At step 1035, a subset of objects is established as a set of objects-under-test. For example, a rectangular array of four objects by four objects in the lower left hand corner of the array may be selected as the set of objects-under-test. At step 1040, the array of objects is configured so that the set of objects-under-test and the SOIs 810 (FIG. 8) communicate via a set of intermediate objects. For example, the objects directly to the north may transmit data via the north and south party line communication channels. Likewise, the objects directly to the east may transmit data via the east and west party line communication channels.

At step 1045, the objects-under-test are tested. According to one embodiment, the testing includes setting the objects-under-test to an initial condition or object configurations. For example, one of the objects-under-test may be configured to communicate with a different one of the objects-under-test using a party line communication channel (e.g., via a party line scan chain). In addition, one of the objects-under-test may be configured to communicate with an adjacent object outside of the set of objects-under-test (e.g., by pulling data from a nearest neighbor register of an adjacent object). Further, the primary functionality of the objects-under-test may be configured using a configuration scan chain and any memories within the objects-under-test may be configured using a latch scan chain.

Once the objects-under-test are set to an initial condition, the objects-under-test are stimulated with a test pattern via the set of intermediate objects. For example, a full speed clock may drive the set of intermediate objects and the objects-under-test. This allows a pseudo-random test pattern generated by the LSFRs 811 (FIG. 8) to propagate to the objects-under-test via the party line communication channels within the set of intermediate objects (e.g., one hop per clock cycle). Outputs from the objects-under-test may also propagate to the MISRs 812 via the party line communication channels within the set of intermediate objects. The MISRs 812 may compress the outputs into a signature. After the full speed clock operates for a certain number cycles, the objects-under-test may be reconfigured and tested again before a new set of objects-under-test is established. According to one embodiment, the full speed clock will operate for a sufficient number of cycles to allow the outputs from the objects-under-test to propagate to the MISRs 812. In addition, the number of reconfiguration iterations may be selected such that the outputs represent a statistically signification portion of a total number of configurations of the objects-under-test. According to one embodiment, the number of reconfiguration iterations is set at approximately 200 and the number of clock cycles at each iteration is set to approximately 100.

At step 1050, a new set of objects-under-test is established to include a different subset of objects. Steps 1040, 1045, and 1050 may repeat until step 1055 determines that every object in the array has been included in at least some number (e.g., 1) of sets of objects-under-test. Once every object in the array has been included in at least one set of objects-under-test, the signatures 813 in all the SOIs 810 may be serially shifted around the array and compressed into a final signature. At step 1060, the final signature is compared to an expected value to determine whether the array of objects if functioning properly. According to one embodiment, step 1050 involves shifting the objects-under-test one column to the east. Then steps 1040, 1045, and 1050 may be repeated until the objects-under-test reaches the east-most column in the array. At this point, the objects-under-test may be shifted up one row and steps 1040, 1045, and 1050 may be repeated again until the objects-under-test reaches the east-most column. The cycle in this embodiment repeats until the set of objects-under-test reaches the north-east corner of the array.

FIG. 11 illustrates various components used to test an FPOA according to one embodiment. The components shown in FIG. 11 may operate in a high-speed domain, a low-speed domain, or a combination of both domains. For example, objects 1100, which operate in the high-speed domain, may be configured, initialized, debugged, and/or tested using components 1105 (collectively a PROM controller 110, a JTAG controller 1115, a scan chain controller 1120, and a BIST controller 1125), which operate in a low-speed domain. Although multiple components 110s are shown, the functions of the components 1005 may be further granularized into other components or maybe combined into one or more overall components.

According to one embodiment, the FPOA checks whether it should load its configuration information via PROM or a JTAG interface upon power-up (see FIG. 6). If a PROM is present (e.g., as indicated by a package pin), a PROM controller 1110 may oversee the configuration and initialization of the FPOA based on configuration information stored in the PROM. If no PROM is present, a JTAG controller 1115 oversees the configuration and initialization of the FPOA. As previously described with reference to FIG. 7, a scan chain controller 1120 (e.g., a scan chain controller similar to the scan chain controller 710) may be used to shift configuration information into the objects 1100 via one or more scan chains 1121, 1122, and 1123.

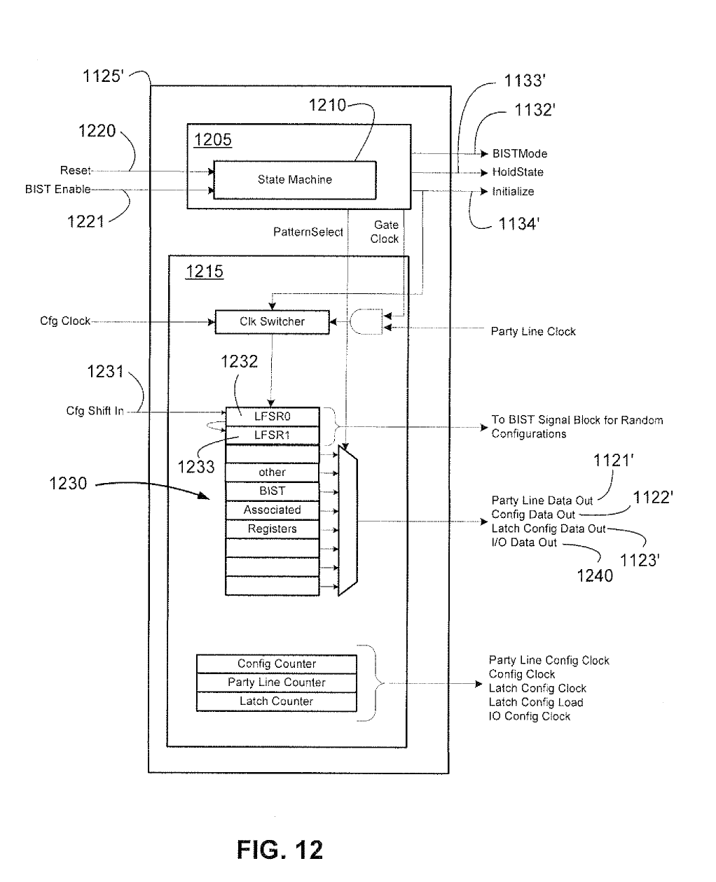

As will be described in more detail with reference to FIG. 12, the BIST controller 1125 may configure objects 1100, apply a stimulus to a set of objects 1100 included within the RUT, and observe a response of the RUT to the stimulus. The BIST controller 1125 may download various configuration parameters via the PROM controller 1110 and/or the JTAG controller 1115. According to one embodiment, the BIST controller 1125 commandeers the scan chain controller 1120 to configure the objects 1100 via the scan chains 1121, 1122, and 1123.

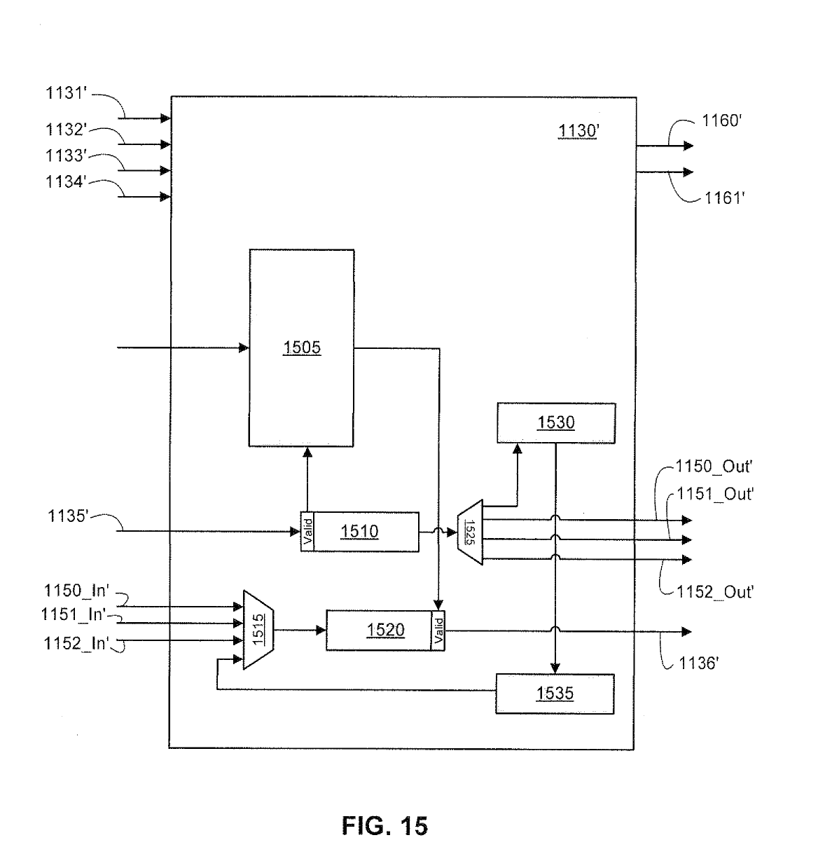

According to one embodiment, a BIST signal block 1130 connects the BIST controller 1125 to the objects 1100 and SOIs 1140-1145. Thus, the BIST signal block 1130 spans the high-speed and low-speed domains. As will be described in more detail with reference to FIG. 15, the BIST signal block 1130 may transmit various signals to and from the low-speed components 1105. For example, the BIST signal block 1130 may receive a “Resetn” signal 1131, a “BISTMode” signal 1132, a “HoldState” signal 1133, an “Initialize” signal 1134, and “Bndry_Data_IN” signal 1135. The Resetn or similar signal 1131 may reflect a chip reset signal synchronized with a PROM clock or JTAG clock. The BISTMode or similar signal 1132 may indicate that BIST is running. The HoldState or similar signal 1133 may tell the objects 1100 whether to connect to the high-speed clock and run at full speed. In other words, the HoldState signal 1133 may effectively allow the objects 1100 to be paused. The Initialize or similar signal 1134 may tell the objects 1100 to load their initial states or configuration set-up data. According to one embodiment, the initial states are determined by the data that was shifted in via the configuration scan chain 1122 and latch scan chain 1123. The Bndry_Data_IN signal 1135 may carry data that used to drive LFSR, MISR, and signature scan chains.

The BIST signal block 1130 may also transmit a Bndry_Data_OUT signal 1136. The Bndry_Data_OUT signal 1136 may communicate to the components 1105 various output values from the high-speed scan chains, such as a final BIST signature, an output from the LFSR, MISR, and signature scan chains.

The BIST signal block 1130 may also communicate with a chain of SOIs 1146. For example, the BIST signal block 1130 may drive signature scan chain data, MISR scan chain data, and LFSR scan chain data to SOI 1140 via lines 1150_OUT, 1151_OUT, and 1152_OUT, respectively. Likewise, the BIST signal block 1130 may receive signature scan chain data, MISR scan chain data, and LSFR scan chain data from SOI 1145 via lines 1150_IN, 1151_IN, and 1152_IN, respectively.

According to one embodiment, the BIST signal block 1130 also communicates with the objects 1100. For example, the BIST signal block 1130 may tell the objects 1100 to pause via the HoldState signal 1160 and load their initial states (as may be determined by the data shifted in via the configuration scan chain 1122 and latch scan chain 1123) via the Initialize signal 1161.

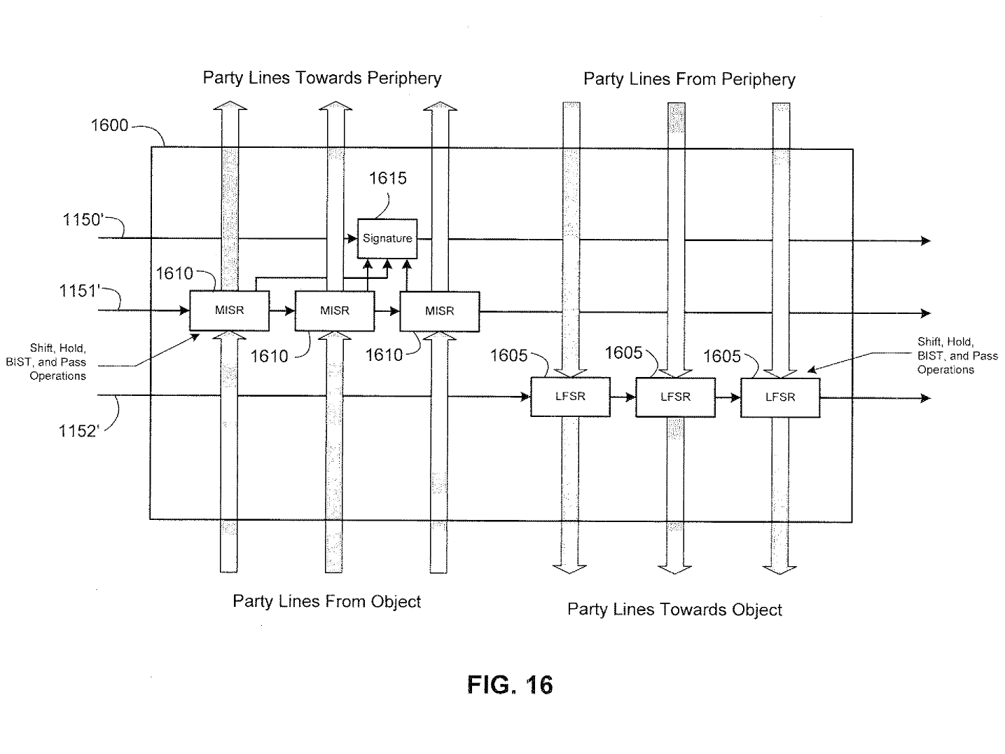

According to one embodiment, the SOIs 1140-1145 communicate with objects 1100. For example, as will be described in more detail with respect to FIG. 16, the SOI 1140 may communicate with a particular object 1180 via a first east-west party line communication channel 1170 and/or a second east-west party line communication channel 1171. Likewise, the SOI 1145 may communicate with the object 1180 via a first north-south party line communication channel 1172, a second north-south party line communication channel 1173, and/or a third north-south party line communication channel 1174.

FIG. 12 is a block diagram of one example of the BIST controller 1125, according to one embodiment. A previously indicated, the BIST controller 1125 may operate in the low-speed domain. For explanation purposes, the BIST controller 1125 may be divided into two functional blocks: (1) a BIST control block 1205 that includes a state machine 1210; and (2) a BIST scan chain control block 1215.

According to one embodiment, the BIST state machine 1210 configures the objects, starts and stops full speed operation of the objects, stimulates the objects within the RUT, and observes a response of the objects within the RUT to the applied stimulus. In other words, the BIST state machine 1210 may execute the methods 1000 and 1030 described with reference to FIGS. 10A and 10B or other BIST methods. According to one embodiment, the BIST state machine 1210 remains idle until initialized (see, e.g., FIG. 6). For example, a reset signal 1220 may initialize the BIST state machine 1210 when the FPOA is powered up. In addition, a JTAG controller (e.g., the JTAG controller 1115 in FIG. 11) may activate the BIST state machine 1210 via a BIST enable signal 1221.

As described with reference to FIG. 11, the BIST state machine 1210 may cooperate with the BIST signal block 1130. For example, the BIST state machine 1210 may generate a “BISTMode” signal 1132′, a “HoldState” signal 1133′, and an ‘Initialize’ signal 1134′ (in FIG. 12 reference numerals with the prime symbol, e.g., 1132′, indicate elements similar to those of the same name as those described with respect to FIG. 11, i.e., the BISTMode signal 1132). However, according to one embodiment, before the BIST state machine 1210 configures the objects in the array and initializes BIST, the BIST state machine 1210 obtains configuration parameters, for example, from the JTAG controller and/or PROM controller.

The configuration parameters may include one or more of the following: (1) RUT size parameters, such as a width and height of the RUT and a starting location of the RUT; (2) RUT shifting parameters, such as a number of times the RUT needs to be shifted right and a number of times the RUT needs to be shifted up; (3) RUT testing parameters, such as a number of clock cycles the objects in the RUT should be operated before altering the configuration within the RUT and a total number of times the configuration of the objects within the RUT should be altered before moving the RUT; (4) party line configuration parameters, such as a predetermined set of party line configurations that will be used to configure the fully powered up objects, the partially powered up objects, and the fully powered down objects and a predetermined set of select codes for specifying which of the predetermined party line configurations will be used for the objects within the RUT; and (5) object configuration parameters, such as seed values used to seed pseudorandom generators that may be used to pseudo-randomly configure the objects (e.g., seeds for LFSR0 1232 and LSFR1 1233). According to one embodiment, the configuration parameters are included as part of a BIST configuration scan chain that is shifted into registers 1230 within the BIST scan chain control block 1215 via a “Cfg Shift In” or similar signal 1231.

According to one embodiment, the BIST scan chain control block 1215 includes two internal 32-bit LFSR registers 1232 and 1233. The two LFSR registers 1232 and 1233 may be used to supply pseudo-random data to the configuration scan chains and latch scan chains (e.g., 1122′ and 1123′). In addition, the two LFSR registers may be used to supply pseudo-random data to a input/output scan chain that is used to configure objects in the periphery region (e.g., IRAM). While the LFSR registers 1232 and 1233 may be implemented using any feedback polynomial, a feedback polynomial according to one embodiment is set forth in the following equation, in which the terms present correspond to positions in the register where feedback connections are present (e.g., the first flip-flop, fifth flip-flop, sixth flip-flop, and thirty-first flip-flop), according to accepted conventions for specifying the construction of LFSRs:

P(x)=x+x⁵+x⁶+x³¹.

The BIST state machine 1210 may shift pseudo-random data into the objects using the configuration scan chain 1122′ during the initial configuration of the objects. In addition, if the configuration of the objects changes iteratively before moving the RUT, one or more bits of pseudo-random data may be shifted onto the configuration scan chain 1122′. The pseudo-random data may be supplied by the two 32-bit LFSR registers 1232 and 1233. While the pseudo-random data may be selected in other ways, according to one embodiment, the pseudo-random data is selected by concatenating the first 20 bits of the LFSR 1232 following by the first 20 bits of the LFSR 1233. Since there may actually be two configuration scan chains, one scan chain can pull twenty bits from the LFSR 1232 while the other scan chain pulls twenty bits from the LSFR 1233.

In a similar vein, the BIST state machine 1210 may shift in pseudo-random data using the latch scan chain 1123′ during the initial configuration of the objects. In addition, if the configuration of the objects changes iteratively before moving the RUT, according to one embodiment, three or more bits of pseudo-random data may be shifted onto the latch scan chain 1123′. For example, an ALU object may need three new bits of data from the latch scan chain to create a new instruction for the ALU object. Thus, during each reconfiguration iteration, the latch scan chain 1123′ may shift in three new pseudo-random bits instead of just one. Because an RF object may not need to be updated with new content, RF objects may be configured to simply pass incoming data on the latch scan chain 1123′ to downstream objects. The pseudo-random data may be supplied by the two 32-bit LFSR registers 1232 and 1233. While the pseudo-random data may be selected in other ways, according to one embodiment, the pseudo-random data is selected by concatenating the last ten bits of the LFSR 1232 followed by the last ten bits of the LFSR 1233. Since there may be only one latch scan chain, the latch scan chain may pull ten bits from LFSR 1232 and ten bits from LSFR 1233.

Likewise, the BIST state machine 1210 may shift in pseudo-random data using an I/O scan chain 1240 during the initial configuration of the objects. In addition, if the configuration of the objects changes iteratively before moving the RUT, according to one embodiment, one or more bits of pseudo-random data may be shifted onto the I/O scan chain 1240. The pseudo-random data may be supplied by the two 32-bit LFSR registers 1232 and 1233. While the pseudo-random data may be selected in other ways, according to one embodiment, the pseudo-random data is selected as the first four bits from the LFSR 1232.

As previously described with reference to FIGS. 8-10, according to one embodiment, objects are the focus of BIST. The objects in the array may be separated into objects-under-test (e.g., objects within the RUT) and objects not under test (e.g., objects outside of the RUT). The objects on the perimeter of the RUT may receive pseudo-random stimulus from adjacent objects via nearest neighbor communication channels. The data pulled from the nearest neighbor registers of adjacent objects may be placed in the nearest neighbor registers during the initial configuration (e.g., via one of the scan chains, such as the configuration scan chain and/or the latch scan chain). The objects on the perimeter of the RUT may also receive pseudo-random stimulus that propagated from the LFSRs in SOIs via the party line communication channels.

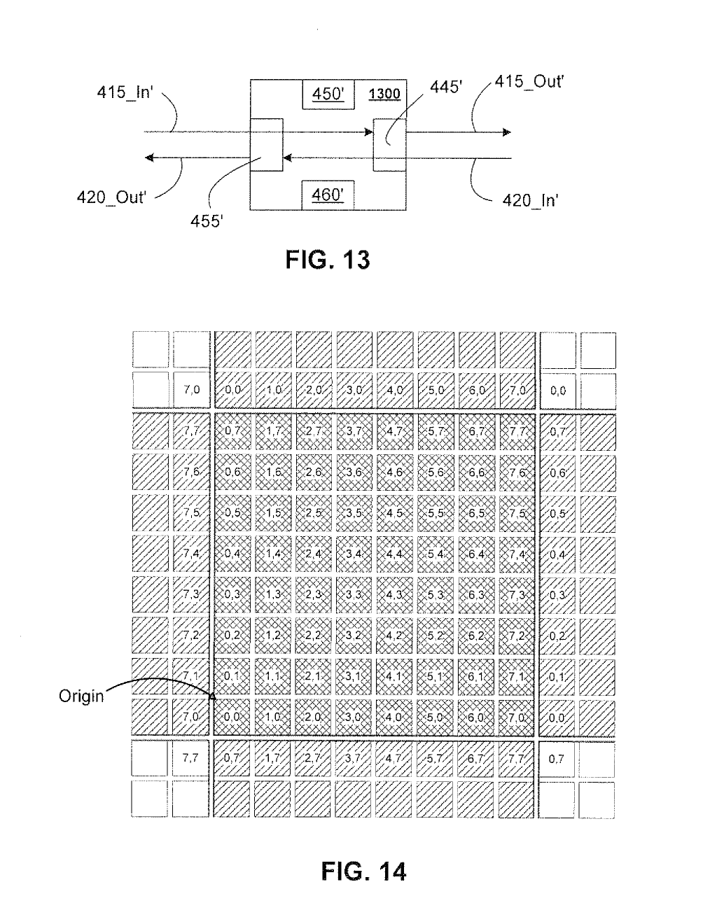

According to one embodiment, eight party line configurations are shifted into the registers 1230 within the BIST scan chain control block 1215 along with other configuration parameters. Of course, additional or fewer party line configurations are possible. The objects not under test may have one of three party line configurations: (1) party lines disabled; (2) east-west party lines configured for retiming, and (3) north-south party lines configured for retiming. In the first configuration, all of an object's party line communication channels are powered down. When in the second configuration, an object's east and west party line communication channels may be configured to retime values (e.g., see FIG. 13) while the north and south party line communication channels are powered down. In a similar vein, when an object is in the third configuration, its north and south party line communication channels may be configured to retime values (e.g., see FIG. 13) while the east and west party line communication channels are powered down.

FIG. 13 illustrates a configuration for east-west party line retiming, according to one embodiment, for an object 1300. The object 1300 may have its north and south party line communication channels powered down, while its east and west party lines are powered up. According to one embodiment, multiplexer 485 (see FIG. 4) may direct party line communication channel 415_IN′ data to land in party line east register 445′ (in FIG. 13 reference numerals with the prime symbol, e.g., 445, indicate elements similar to those of the same name as those described with respect to FIG. 4, i.e., the party line east register 445). Multiplexer 425 (see FIG. 4) may then be configured to launch data directly from the party line east register 445′ onto party line communication channel 415_OUT′. Likewise, multiplexer 480 (see FIG. 4) may direct party line communication channel 420_IN′ to land data in party line west register 455′. Multiplexer 435 (see FIG. 4) may then be configured to launch data directly from the party line west register 455′ onto party line communication channel 420_OUT′. The party line retime north-south configuration may be implemented in a similar manner, except using party line north register 450′ and party line south register 460′.

Objects within the RUT may be configured to use any number of party line configurations. As previously discussed with reference to FIG. 12, party line configurations may be downloaded into registers 1230 within the BIST scan chain control block 1215 via a BIST configuration scan chain prior to initiating the BIST state machine 1210. For example, eight 378-bit party line configurations may be downloaded. The eight party line configurations may be selected to optimize as many BIST characteristics (e.g., test coverage, test time, power consumption, test generation complexity, etc.) as possible. However, some of the characteristics may be in tension with one another especially in view of a particular set of circuitry (e.g., the circuitry within an object's core, such as an ALU, MAC, and RF, or the circuitry within the object's communication infrastructure). Thus, it may be necessary to design more than one set of eight party line configurations. For example, a first set of eight party line configurations may be optimized to test circuitry within an object's core and a second set of eight party line configurations may be optimized to test circuitry within an object's communication infrastructure. A FPOA may be programmed with the first set of party line configurations and tested to determine whether the FPOA's core circuitry is functioning properly. Then, the same FPOA may be reprogrammed with the second set of eight party line configurations and retested to determine whether the FPOA's communication infrastructure circuitry is functioning properly. Of course, the same FPOA may be reprogrammed and retested any number of times. However, the total number of times the FPOA is reprogrammed and retested may be limited by the total time it takes to test each FPOA. Thus, it should be noted that selecting party line configurations to optimize as many BIST characteristics as possible may depend upon the particular FPOA being tested (e.g., the array size of the FPOA, the operating speed of the FPOA, the power consumption of the FPOA, etc.).

The eight party line configurations may include the three party line configurations previously described with reference to the objects not under test (i.e., party lines disabled, east-west party lines configured for retiming, and north-south party lines configured for retiming). In addition, the eight party line configurations may be optimized to test circuitry within an object's core. By way of example, the party line configurations for objects within a RUT may be selected such that a result from each object's core is launched onto one of the party lines so that the result is observable outside of the RUT. Further, the eight party line configurations may be optimized to test circuitry within an object's communication infrastructure. By way of example, party line configurations may be selected to explore as many party line launch multiplexer (e.g., multiplexers 425, 430, 435, and 440 of FIG. 4) and land multiplexer (e.g., multiplexers 470, 475, 480, and 485 of FIG. 4) configurations as possible.

According to one embodiment, each object in the array will have only one of the eight party line configurations applied at a time. The party line configurations may be the same for all object types regardless of the objects functionality (e.g., ALUs, RFs, or MACs). According to one embodiment, a table downloaded as part of the BIST scan chain defines which of the eight party line configurations applies to each object within an eight-by-eight RUT. The table may be implemented by an eight-by-eight array of 3-bit fields, each corresponding to a specific object in the RUT. Of course, a RUT smaller or larger than eight-by-eight objects may be used. A larger RUT may be provided using additional bits (e.g., 4-bits). In addition, configurations from the eight-by-eight array may be repeated in a modulo-eight fashion to provide a larger RUT.

FIG. 14 illustrates how coordinates within an eight-by-eight array may be designated. As shown in FIG. 14, the southwest object may have coordinates [0,0] (or 000,000 in binary). Likewise, the northeast object may have coordinates [7,7] (or 111,111 in binary). According to one embodiment, the table may include three fields: (1) one field to designate a relative east/west position (as measured from a reference point); (2) a second field to designate a relative north/south position; and (3) a third field designating which of the eight party line configurations applies to the relatively defined object.

Because, according to one embodiment, only eight possible party line configurations are used, only a subset of local resources (e.g., nearest neighbor registers and party line landing registers) will be launched from any given object within the RUT. Therefore, it may be necessary to reconfigure the objects within the RUT with different party line configurations (before moving the RUT) to provide full visibility to an object's local resources. In addition, reconfiguring the objects within the RUT may allow testing of other launch multiplexer selections (e.g., passing and turning) and hop count behavior. In other words, to fully exercise the objects, multiple party line configurations may be necessary and/or desirable.

By using the party-lines-disabled configuration for one or more of the objects within the RUT, a hole may be created in the RUT. This may allow the RUT to be larger than if all the objects were powered up and may be useful in testing large hop counts, such as when a slower core clock speed is used. In addition, an entire column or row may be the RUT. This may result in another party line configuration to be downloaded in place of, for example, the party line retime east-west or the party line retime north-south configuration.

As previously mentioned, while eight party line configurations may be used, additional or fewer party line configurations are possible. The following example illustrates testing a twenty-by-twenty array using four RUTs having various party line configurations.

Initially, the twenty-by-twenty FPOA is programmed with a first set of party line configurations and tested to determine whether the FPOA's core circuitry is functioning properly. To minimize power consumption, a two-by-two RUT is used. Because a smaller RUT is being used, a simpler addressing schema is used (as compared to FIG. 14). For example, the four objects in the RUT may be addressed as follows. The lower left object may have an address of 0 (00 in binary), the lower right object may have an address of 1 (01 in binary), the upper left object may have an address of 2 (10 in binary), and the upper right object may have an address of 3 (11 in binary). Next, a table downloaded as part of the BIST scan chain defines which of four party line configurations applies to each object within the two-by-two RUT. The four party line configurations may be identified as configuration 1, 2, 3, or 4 and implemented using a two-bit binary number. The table may dictate that object 1 has party line configuration 1, object 2 has party line configuration 2, and so forth. However, other correspondences are possible.

As described with reference to FIG. 4, each object may have ten party line communication channels divided into three groups: (1) a first group of channels heading north, south, east, and west; (2) a second group of channels heading north, south, east, and west; and (3) a third group of channels heading north and south. FIG. 4 illustrates both the first and second groups. The third group would be represented by a schematic diagram similar to that illustrated in FIG. 4, but without the party line communication channels heading east and west. Thus each object according to the FIG. 4 embodiment would have ten launch multiplexers (three similar to multiplexer 430, three similar to multiplexer 440, two similar to multiplexer 425, and two similar to multiplexer 435). For discussion purposes, the ten launch multiplexers will be referred to as 425a-b, 430a-c, 435a-b, and 440a-c. In a similar vein, each object has ten party line communication channels (which will be referred to as 405a-c, 410a-c, 415a-b, and 420a-b), ten party line registers (which will be referred to as 445a-b, 450a-c, 455a-b, and 460a-c), and ten landing multiplexers (which will be referred to as 470a-c, 475a-c, 480a-b, and 485a-b). However, each object includes only four nearest neighbor registers (i.e., 447, 452, 457, and 462).

The following table illustrates four party line configurations along with an indication of how each launch multiplexer's selector would be set. For example, with reference to FIG. 4, multiplexer 430a launches data from nearest neighbor register 452 when the object is in configurations 1 and 2 and multiplexer 430a launches data from nearest neighbor register 447 when the object is in configurations 3 and 4. By way of another example, multiplexer 440a launches data from nearest neighbor register 457 when the object is in configurations 1 and 2 and multiplexer 440a launches data from nearest neighbor register 462 when the object is in configurations 3 and 4. As indicated in the table, multiplexers 430c and 440c launch data from the core 465 when the object is in configurations 2 and 3 and configurations 1 and 4, respectively. Although not specifically illustrated in FIG. 4, the launch multiplexers (e.g., multiplexers 430c and 440c) can launch data directly from the core 465. Launching data directly from the core 465 allows the internal state of the core 465 to be more readily observed. It should be noted that launching data from the core 465 may be accomplished in other ways, such as by reclocking the data in a data register.

Launch Multiplexer

| | | 430a | 430b | 430c | 440a | 440b | 440c | 425a | 425b | 435a | 435b |
|---|---|---|---|---|---|---|---|---|---|---|---|
| Configuration | 1 | 452 | 447 | 452 | 457 | 462 | 465 | 447 | 462 | 457 | 452 |
| | 2 | 452 | 447 | 465 | 457 | 462 | 457 | 447 | 462 | 457 | 452 |
| | 3 | 447 | 452 | 465 | 462 | 457 | 462 | 462 | 447 | 452 | 457 |
| | 4 | 447 | 452 | 447 | 462 | 457 | 465 | 462 | 447 | 452 | 457 |

As will be apparent from studying the launch multiplexer table, the party line configurations for objects within the two-by-two RUT have been selected so that a result from each object's core is launched onto one of the party lines (either directly or indirectly via a register). Thus, the internal core logic associated with the object is readily observable outside of the RUT. In other words, the final BIST signature would be probative of the functionality of the FPOA's core logic.

The following table illustrates the four party line configurations discussed above along with an indication of how each land multiplexer's selector would be set. For example multiplexer 470a lands data from the core 465 when the object is in configurations 1 and 2 and multiplexer 470a lands data from party line communication channel 410a when the object is in configurations 3 and 4. By way of another example, multiplexer 475a lands data from party line communication channel 405a when the object is in configurations 1 and 2 and multiplexer 475a lands data from the core 465 when the object is in configurations 3 and 4. When the landing multiplexer lands data from the core 465, the object is essentially re-circulating internal core logic result states. When the landing multiplexer lands data from one of the party line communication channels, pseudorandom data (from the LFSRs in the SOIs) is brought into the object for use by the core 465.

Land Multiplexer

| | | 470a | 470b | 470c | 475a | 475b | 475c | 485a | 485b | 480a | 480b |
|---|---|---|---|---|---|---|---|---|---|---|---|
| Configuration | 1 | 465 | 410b | 465 | 405a | 465 | 405c | 465 | 415b | 465 | 420b |
| | 2 | 465 | 410b | 410c | 405a | 465 | 405c | 465 | 415b | 465 | 420b |
| | 3 | 410a | 465 | 410c | 465 | 405b | 465 | 415a | 465 | 420a | 465 |
| | 4 | 410a | 465 | 410c | 465 | 405b | 405c | 415a | 465 | 420a | 465 |

Next, the twenty-by-twenty FPOA is reprogrammed three more times with a second, third, and fourth set of party line configurations and retested each time it is reprogrammed to determine whether the FPOA's party line interface logic is functioning properly.

The following table illustrates launch multiplexer selections for the second set of party line configurations. A two-by-two RUT is again used to test the twenty-by-twenty FPOA. As discussed above, a table downloaded along with the party line configurations defines which of four party line configurations applies to each object within the two-by-two RUT. As the following table illustrates each party line configurations dictates how each launch multiplexer's selector would be set. For example, multiplexer 430a turns data from party line communication channel 415a when the object is in configuration 1, turns data from party line communication channel 420a when the object is in configuration 2, and passes data from party line communication channel 410a when the object is in configurations 3 and 4. By way of another example, multiplexer 440a passes data from party line communication channel 405a when the object is in configurations 1 and 2, turns data from party line communication channel 415a when the object is in configuration 3, and turns data from party line communication channel 420a when the object is in configuration 4. As previously described, the third group of channels heading north and south do not have party line communication channels heading east and west Thus, multiplexer 430c passes data from party line communication channel 410c when the object is in configurations 1, 2, 3, and 4. Likewise, multiplexer 440c passes data from party line communication channel 405c when the object is in configurations 1, 2, 3, and 4.

Launch Multiplexer

| | | 430a | 430b | 430c | 440a | 440b | 440c | 425a | 425b | 435a | 435b |
|---|---|---|---|---|---|---|---|---|---|---|---|
| Configuration | 1 | 415a | 415b | 410c | 405a | 405b | 405c | 410a | 410b | 420a | 420b |
| | 2 | 420a | 420b | 410c | 405a | 405b | 405c | 415a | 415b | 410a | 410b |
| | 3 | 410a | 410b | 410c | 415a | 415b | 405c | 405a | 405b | 420a | 420b |
| | 4 | 410a | 410b | 410c | 420a | 420b | 405c | 415a | 415b | 405a | 405b |

Each land multiplexer's selector is set so that data traveling in a certain direction will land in an appropriate party line register such that it will be launched in the same direction with the next clock cycle. For example, landing multiplexers 470a-c land data from party line communication channels 410a-c into party line registers 450a-c, respectively. Likewise, landing multiplexers 485a-b land data from party line communication channels 415a-b into party line registers 445a-b, respectively.

As will be apparent from the landing multiplexer description and from studying the above launch multiplexer table, the party line configurations for objects within the two-by-two RUT have been selected to test circuitry within an object's communication infrastructure. In other words, the party line configurations have been defined to test as many party line launch multiplexer (e.g., multiplexers 425, 430, 435, and 440 of FIG. 4) and land multiplexer (e.g., multiplexers 470, 475, 480, and 485 of FIG. 4) configurations as possible.

The third set of party line configurations are defined to test an entire row of the twenty-by-twenty FPOA at a time. Testing an entire row at once may be useful in testing hop count. To accomplish this, a twenty-by-one RUT is used to test the FPOA. Each object in the RUT has a uniform party line configuration. All party line launch multiplexers (e.g., multiplexers 425a-b, 430a-c, 435a-b, and 440a-c) for each object are configured to retime data. For example, multiplexers 425a-b launch data from party line registers 445a-b, multiplexers 430a-c launch data from party line registers 450a-c, multiplexers 435a-b launch data from party line registers 455a-b, and multiplexers 440a-c launch data from party line registers 460a-c. The north and south party line landing multiplexers are configured to reflect data. For example, the landing multiplexers 470a-c land data from party line communication channels 405a-c into party line registers 450a-c, respectively. Likewise, the landing multiplexers 475a-c land data from party line communication channels 410a-c into party line registers 460a-c, respectively. The east and west party line landing multiplexers are configured such that data traveling in an east-west direction will land in an appropriate party line register so that it will be launched in the same direction with the next clock cycle. For example, landing multiplexers 480a-b land data from party line communication channels 420a-b into party line registers 455a-b, respectively. Likewise, landing multiplexers 485a-b land data from party line communication channels 415a-b into party line registers 445a-b, respectively.

The fourth set of party line configurations are defined to test an entire column of the twenty-by-twenty FPOA at a time. Testing an entire column at once may be useful in testing hop count. To accomplish this, a one-by-twenty RUT is used to test the FPOA. Each object in the RUT has a uniform party line configuration. As previously described with reference to the twenty-by-one RUT, all party line launch multiplexers for each object are configured to retime data. For example, multiplexers 425a-b launch data from party line registers 445a-b, multiplexers 430a-c launch data from party line registers 450a-c, multiplexers 435a-b launch data from party line registers 455a-b, and multiplexers 440a-c launch data from party line registers 460a-c. With the one-by-twenty RUT, the east and west party line landing multiplexers are configured to reflect data. For example, the landing multiplexers 480a-b land data from party line communication channels 415a-b into party line registers 455a-b, respectively. Likewise, the landing multiplexers 485a-b land data from party line communication channels 420a-b into party line registers 445a-b, respectively. The north and south party line landing multiplexers are configured such that data traveling in a north-south direction will land in an appropriate party line register so that it will be launched in the same direction with the next clock cycle. For example, landing multiplexers 470a-c land data from party line communication channels 410a-c into party line registers 450a-c, respectively. Likewise, landing multiplexers 475a-c land data from party line communication channels 405a-c into party line registers 460a-c, respectively.

To summarize, the twenty-by-twenty FPOA will be tested essentially from two perspectives: (1) each object's internal core logic; and (2) each objects party line interface logic. The internal core logic is tested by programming the FPOA with the first set of party line configurations and testing it using the two-by-two RUT. The party line interface logic is tested using three different RUTs. First, the twenty-by-twenty FPOA is reprogrammed with the second set of party line configurations and retested using the two-by-two RUT. Next, the FPOA is reprogrammed with the third set of party line configurations and retested using the twenty-by-one RUT. Finally, the FPOA is reprogrammed with the fourth set of party line configurations and retested using the one-by-twenty RUT. At each iteration, the final BIST signature may be checked to determine whether the FPOA has passed or failed (which may halt further testing of the FPOA). Further, each iteration may operate at different clock speeds (which may be useful in testing maximum operating frequency and hop count). For example, the first iteration covering core logic may be designed to test the maximum operating frequency of the core logic.

FIG. 15 illustrates a BIST signal block 1130′ according to another embodiment (in FIG. 15 reference numerals with the prime symbol, e.g., 1130′, indicate elements similar to those of the same name as those described with respect to FIG. 11, i.e., the BIST signal block 1130). As previously described with reference to FIG. 11, the BIST signal block 1130′ may span the high-speed and low-speed domains. The BIST signal block 1130′ may include a shift controller 1505 and receives a “Resetn” signal 1131′, a “BISTMode” signal 1132′, a “HoldState” signal 1133′, an “Initialize” signal 1134′, and a “Bndry_Data_IN” signal 1135′, or a similar set of signals. Different embodiments of a BIST signal block may not require the same signals. In addition, the BIST signal block 1130′ may transmit the HoldState signal 1160′ and the Initialize signal 1161′ to the objects.

The BIST signal block 1130′ may include two registers 1510 and 1520 that help interface the high-speed and low-speed components. According to one embodiment, the registers 1510 and 1520 are addressable. By way of example, the Bndry_Data_IN signal 1135′ may carry data that is used to drive a LFSR scan chain 1152_OUT′, a MISR scan chain 1151_OUT′, and a signature scan chain 1150_OUT′ via a de-multiplexer 1525. As described with reference to FIG. 11, the LFSR scan chain 1152_OUT′, the MISR scan chain 1151_OUT′, and the signature scan chain 1150_OUT′ may be coupled to the SOIs located around the perimeter of the array (or otherwise not part of the core region of the FPOA).

The register 1520 may read the signature scan chain 1150_IN′, the MISR scan chain 1151_IN′, LFSR scan chain 1152_IN′, via a multiplexer 1515. These scan chains originate from the SOIs that surround the array. The register 1520 allows the scan chains and a final signature stored in register 1535 to be accessed by components operating in the low-speed domain (e.g., BIST controller 1125 of FIG. 11) via a ‘Bndry_Data_OUT’ signal 1136′.

According to one embodiment, a 32-bit LFSR 1530 may be included within the BIST signal block 1130′ to generate pseudo-random data that is shifted into the LFSR scan chain 1152′ and signature scan chain 1150′. The LFSR register 1530 may be the same or different from the LFSR 1232 in FIG. 11.

The BIST signal block 1130′ may also include a 48-bit final BIST signature register 1535. According to one embodiment, the final BIST signature register 1535 accumulates and compresses the output from the signature scan chain 1150_IN′ each time a RUT completes testing at a particular location. As previously described, when BIST completes, the JTAG controller 1115 (FIG. 11) may query the final BIST signature register 1535 and compare the result to a known good value to determine whether the FPOA is functioning properly. While the final BIST signature register 1535 may be implemented using any feedback polynomial, one suitable polynomial is the following:

P(x)=x²+x⁴⁷.

FIG. 16 is a block diagram illustrating a SOI 1600 according to one embodiment. As previously described with reference to FIG. 8, the SOIs generally surround the array of objects. According to one embodiment, the SOIs serve as party line launching and landing registers during normal operation, provide stimulus to and observability of RUT objects during BIST, and provide debug access to the periphery via the JTAG interface.

The SOIs may be grouped into two broad categories: (1) north-south SOIs; and (2) east-west SOIs. The north-south SOIs reside at the top and bottom of every column in the array and, according to one embodiment, support three party line communication channels. The east-west SOIs reside on the ends of every row in the array and support, for example, two party line communication channels. Of course, the SOIs may reside in other locations and support fewer or additional party line communication channels. Because the SOI 1600 has three party line communication channels, the SOI 1600 represents a column-based SOI.

According to one embodiment, the SOIs contain LFSRs 1605, MISRs 1610, and a signature register 1615. As previously described, the LFSRs 1605 drive pseudo-random data towards the RUT objects. According to one embodiment, there are 200 LFSRs 1605 located around the perimeter of the object array. The LFSRs 1605 may be daisy chained to form a LFSR scan chain and may be accessed via the LFSR scan chain 1152′ (in FIG. 16 reference numerals with the prime symbol, e.g., 1152′, indicate elements similar to those of the same name as those described with respect to FIG. 11, i.e., the LFSR scan chain 1152). The MISRs 1610 may accumulate incoming information in a CRC (cyclic redundancy check)-like fashion. According to one embodiment, there are 200 MISRs 1610 located around the perimeter of the object array. The MISRs 1610 may also be daisy chained to form a MISR scan chain and may be accessed via the MISR scan chain 1151′. The signature register 1615 may accumulate and compress data from the MISR blocks 1610 after each inner-loop iteration of the BIST (e.g., after each reconfiguration of the RUT before the RUT is moved). According to one embodiment, there are approximately 80 signature registers 1615 located around the object array. The signature registers 1615 may be daisy chained and to form the signature scan chain and may be accessed via the signature scan chain 1150′.

According to one embodiment, the MISRs 1610 are 21-bit registers having, for example, 16 bits of data, 1 valid bit, and 4 control bits. While the MISR registers 1610 may be implemented using any feedback polynomial, one suitable polynomial is the following:

P(x)=x²⁰+1.

According to one embodiment, the signature register 1615 is a 16-bit register. While the signature register 1615 may be implemented using any feedback polynomial, one suitable polynomial is the following:

P(x)=x¹+x²+x⁴+x¹⁵.

According to one embodiment, the SOI LFSRs 1605 are 21-bit registers (e.g., 16-bits of data, 1 valid bit, and 4 control bits). While the LFSR registers 1605 may be implemented using any feedback polynomial, one suitable polynomial is the following:

P(x)=x²⁰+1.

While the SOIs are placed around the periphery of the objects according to one embodiment, other configurations are possible. For example, the SOIs may simply be connected in some manner to the objects to enable communication with objects in the non-core region (e.g., periphery region 110 of FIG. 1). As such, the SOIs may be located in a separate physical plane with respect to the objects (e.g., on top of or underneath the objects). Further, one or more of the objects may be connected to one or more SOIs adjacent the objects.

According to one embodiment, BIST may be initiated by a driver, communicating with the FPOA via the JTAG interface. During BIST, periphery object configurations may change in a random-like manner. This might cause periphery object outputs that drive external FPOA pins to change state (e.g., the bi-directional GPIO pins may toggle direction between input to output). Accordingly, according to one embodiment, the FPOA is disconnected from its pins before running BIST. For example, after asserting the self-clearing chip reset, an instruction may be written to a JTAG instruction register to inhibit output pins from changing state while the JTAG boundary scan chain preloads. In addition, the JTAG boundary scan chain may be loaded to a safe state. For example, the FPOA may operate in a state that allows cells that compose the JTAG boundary scan chain to connect directly to FPOA pins. This may allow the outputs to remain in a safe state as BIST testing occurs. In addition, boundary scan cells may force pins to a static bi-directional state.

Next, the JTAG boundary scan chain may be loaded to a safe state so that output pins do not change state and the GPIO bi-direction pins do not change from input to output. After setting the self-clearing JTAG reset bit in the JTAG control register, the BIST sub-system is ready to be configured (e.g., specifying the number of clock to run in BIST state; specifying an additional amount of time to continue shifting the LFSR scan chain to account for pipeline latency in clocks; and shifting in BIST configuration scan chain content).

After configuring the BIST sub-system, BIST may be initiated by setting a self-clearing BIST enable bit in the BIST control register. While BIST is running, a BIST busy bit in a status control register may be polled to check when BIST is finished. According to one embodiment, BIST may run for approximately 10 msec (milliseconds or one-thousandth of a second) assuming a 20 MHz slow clock.

After BIST completes, the final BIST signature register may be read and compared with an expected result to determine whether the FPOA is functioning properly (e.g., whether it passed or failed). A failure, for example, might be caused by physical flaws or timing flaws within the FPOA. Access to the final BIST signature register may be enabled using a scan chain address control register.

The methods and systems for testing an integrated circuit may be implemented in and/or by any suitable hardware, software, firmware, or combination thereof. Accordingly, as used herein, a component or module may comprise hardware, software, and/or firmware (e.g., self-contained hardware or software components that interact with a larger system). Embodiments may include various steps, which may be embodied in machine-executable instructions to be executed by an FPOA or other processor. Alternatively, the steps may be performed by hardware components that include specific logic for performing the steps or by a combination of hardware, software, and/or firmware. A result or output from any step, such as a confirmation that the step has or has not been completed or an output value from the step, may be stored, displayed, printed, and/or transmitted over a wired or wireless network. For example, a determination of whether the FPOA is functioning properly (e.g., whether it passed or failed BIST) based on the final BIST signature may be stored, displayed, or transmitted over a network.

Embodiments may also be provided as a computer program product including a machine-readable storage medium having stored thereon instructions (in compressed or uncompressed form) that may be used to program a computer (or other electronic device) to perform processes or methods described herein. The machine-readable storage medium may include, but is not limited to, hard drives, floppy diskettes, optical disks, CD-ROMs, DVDs, read-only memories (ROMs), random access memories (RAMs), EPROMs, EEPROMs, flash memory, magnetic or optical cards, solid-state memory devices, or other types of media/machine-readable medium suitable for storing electronic instructions. Further, embodiments may also be provided as a computer program product including a machine-readable signal (in compressed or uncompressed form). Examples of machine-readable signals, whether modulated using a carrier or not, include, but are not limited to, signals that a computer system or machine hosting or running a computer program can be configured to access, including signals downloaded through the Internet or other networks. For example, distribution of software may be via CD-ROM or via Internet download.

The terms and descriptions used herein are set forth by way of illustration only and are not meant as limitations. Those skilled in the art will recognize that many variations can be made to the details of the above-described embodiments without departing from the underlying principles of the invention. The scope of the invention should therefore be determined only by the following claims (and their equivalents) in which all terms are to be understood in their broadest reasonable sense unless otherwise indicated.

1. An integrated circuit with built-in self-testing capability, the integrated circuit comprising:
an array of programmable objects designed to operate at an operational clock speed during non-testing operation, wherein the design of the objects is not constrained to require within an object extra circuitry not essential to non-testing operation to facilitate built-in self-testing;
a plurality of interfaces connected to the objects to enable communication with the objects and to thereby facilitate built-in self-testing of the objects; and
a controller operably connected to the objects and to the interfaces and configured:
to cause a selected subset of the objects to be activated and configured for testing,
to stimulate the selected subset of objects for a given time with an input test pattern delivered via one or more of the plurality of interfaces while the selected subset of objects operates at the operational clock speed, and
to observe a response of the selected subset of objects for testing purposes.

2. An integrated circuit as set forth in claim 1, wherein the array of programmable objects are located in a central portion of the integrated circuit, and wherein the plurality of interfaces are located in an area of the integrated circuit peripheral to the central portion.

3. An integrated circuit as set forth in claim 1, wherein each interface comprises:
a linear feedback shift register to generate the input test pattern; and
a register connected to receive response data.

4. An integrated circuit as set forth in claim 1, wherein the controller operates at a clock speed less than the operational clock speed.

5. An integrated circuit as set forth in claim 1, wherein the controller is configured to iteratively perform a testing operation on a sequence of different selected subsets of objects until all objects in the array have been included in at least one testing operation, and wherein the controller is further configured to collect a cumulative signature indicative of the results of all testing operations.

6. An integrated circuit as set forth in claim 17 wherein the selected subset of objects is a set of contiguous objects in a rectangle-shaped pattern.

7. An integrated circuit as set forth in claim 1, wherein the array of objects is a rectangular array having between approximately 8 and approximately 64 rows and between approximately 8 and approximately 64 columns.

8. An integrated circuit as set forth in claim 1, wherein an object comprises internal functional circuitry for performing functions within the object and communication circuitry for communicating with other objects in the array and with the interfaces.

9. An integrated circuit as set forth in claim 8, wherein the objects' internal functional circuitry is located in a central region of the object, and the objects' communication circuitry is located in a periphery region of the object.

10. An integrated circuit as set forth in claim 8, wherein the communication circuitry comprises a bus interface to at least one unidirectional segmented bus.

11. An integrated circuit as set forth in claim 8, wherein the communication circuitry comprises a connection to communicate with at least one neighboring object.

12. A method of testing an integrated circuit comprising in substantial part an array of objects in a central region of the integrated circuit and further comprising registers outside of the central region, the method comprising:
(a) establishing a subset of the objects as a set of objects-under-test;
(b) configuring the array of objects so that the set of objects-under-test and a set of the registers communicate via a set of intermediate objects in the array;
(c) testing the set of objects-under-test, said testing comprising:
setting the set of objects-under-test into a configuration;
stimulating the set of objects-under-test with a test pattern via the set of intermediate objects while the set of object-under-test operates; and
receiving an output pattern from the set of objects-under-test in response to the test pattern, the output pattern received at the set of registers via the set of intermediate objects;
(d) establishing a new set of objects-under-test as a different subset of the objects;
(e) repeating steps (b), (c), and (d) until every object in the array has been included in at least one set of objects-under-test.

13. A method as set forth in claim 12, wherein step (b) comprises:
fully powering up the set of objects-under-test;
partially powering up the set of intermediate objects so as to enable object-to-object communication but to disable internal functionality; and
powering down all objects not in either the set of objects-under-test or the set of intermediate objects.

14. A method as set forth in claim 12, wherein the configuration and the test pattern are pseudo-randomly determined.

15. A method as set forth in claim 12, wherein setting the set of objects-under-test into a configuration comprises configuring interconnections of the objects-under-test so that at least one of the objects-under-test is connected to a different one of the other objects-under-test.

16. A method as set forth in claim 12, wherein setting the set of objects-under-test into a configuration comprises configuring interconnections of the objects-under-test so that at least one of the objects-under-test is connected to an adjacent object that is not included within the set of objects-under-test.

17. A method as set forth in claim 12, wherein the integrated circuit comprises a clock that operates at a full speed for internal operation of the objects, and wherein the set of object-under-test operates at the full speed of the clock during the step of stimulating the set of objects-under-test with a test pattern.

18. A method of testing an integrated circuit comprising an array of objects, the method comprising:
fully powering up a set of objects to be tested;
partially powering up another set of objects to allow unidirectional segmented buses included therein to transfer data to and from the fully-powered-up set of objects;
fully powering down any remaining objects of the array, thereby limiting the array's power consumption; and
transmitting a test pattern to the fully powered-up set of objects and an output pattern from the fully powered-up set of objects via the partially powered-up set of objects, the output pattern generated by the fully powered-up set of objects in response to the test pattern.

19. A method as set forth in claim 18, wherein the fully powered-up set of objects is a contiguous set of objects in a rectangular pattern.

20. A method as set forth in claim 18, wherein the integrated circuit comprises a periphery region surrounding the array, the periphery region having west, east, north and south sides, wherein the first subset of objects is characterized by a border having west, east, north, and south sides in a plane of the integrated circuit, and wherein the second set of objects consists of:
all objects in the array directly between the west side of the border and the west side of the periphery region;
all objects in the array directly between the east side of the border and the east side of the periphery region;
all objects in the array directly between the north side of the border and the north side of the periphery region; and
all objects in the array directly between the south side of the border and the south side of the periphery region.

21. A method as set forth in claim 18, further comprising:
compressing the output pattern into a signature indicative of a response of the fully powered-up subset of objects to the test pattern.

22. A method as set forth in claim 21, further comprising:
comparing the signature to an expected value to determine whether the fully powered-up subset of objects is functioning properly.

23. A method as set forth in claim 18, further comprising:
transmitting a second test pattern to the fully powered-up set of objects and an second output pattern from the fully powered-up set of objects via the partially powered-up set of objects, the second output pattern generated by the fully powered-up set of objects in response to the second test pattern.

24. A method as set forth in claim 18, further comprising:
configuring the fully powered-up set of objects in an initial state prior to transmitting the test pattern.

25. A method as set forth in claim 24, further comprising:
repeating a number of times the following steps:
configuring the fully powered-up set of objects in a new initial state; and
thereafter transmitting a test pattern to the fully powered-up set of objects so as to generate a new output pattern.
